(19) United States
(12) Patent Application Publication
(10) Pub. No.: US 2017/0301805 A1
(43) Pub. Date: Oct. 19, 2017

(54) SOLAR CELL MANUFACTURING METHOD AND SOLAR CELL

(71) Applicant: Mitsubishi Electric Corporation, Chiyoda-ku (JP)

(72) Inventors: Hiroya YAMARIN, Tokyo (JP); Takayuki MORIOKA, Tokyo (JP); Takeo FURUHATA, Tokyo (JP)

(73) Assignee: Mitsubishi Electric Corporation, Chiyoda-ku (JP)

(21) Appl. No.: 15/517,087

(22) PCT Filed: Nov. 16, 2015
(86) PCT No.: PCT/JP2015/082129

§ 371 Date: Apr. 5, 2017

(30) Foreign Application Priority Data
Nov. 21, 2014 (JP) 2014-236920

(51) Int. Cl. H01L 31/0224; H01L 31/0312; H01L 31/0216; H01L 31/18; H01L 31/068

(52) U.S. Cl. CPC H01L 31/022433; H01L 31/18; H01L 31/068; H01L 31/02168; H01L 31/022425; H01L 31/03125

(57) ABSTRACT

A solar cell manufacturing method including: forming, on one surface of a first conductivity-type semiconductor substrate, a first doped layer in which second conductivity-type impurities are diffused in a first concentration, and a second doped layer in which the second conductivity-type impurities are diffused in a second concentration lower than the first concentration, the second doped layer has surface roughness different from the first doped layer; and forming a metal electrode on the first doped layer to be electrically connected to the first doped layer, wherein a position of the first doped layer is detected based on a difference in light reflectance between the first and second doped layers, which results from a difference in surface roughness between the first and second doped layers, and then the metal electrode is formed in alignment with a detected position of the first doped layer.

### FIELD

The present invention relates to a manufacturing method of a solar cell having a selective emitter structure, and also relates to a solar cell.

### BACKGROUND

In crystalline silicon solar cells, a selective emitter structure is used in order to improve the photoelectric conversion efficiency. The selective emitter structure is a structure in which, in an impurity diffusion region formed on a silicon substrate, the area to be connected to an electrode is formed with a higher surface-impurity concentration than the light receiving portion. In the selective emitter structure, a contact resistance between the silicon substrate and the electrode is reduced. Further, a lower impurity diffusion concentration in the light receiving portion can suppress recombination of carriers in the light receiving portion. Therefore, improvement in the photoelectric conversion efficiency is achieved.

As a common method for forming a selective emitter structure, Patent Literature 1 has disclosed the method to apply a paste or the like onto a semiconductor substrate by the screen printing method to selectively form a diffusion layer, in which impurities such as boron are diffused in a high concentration, on the light receiving surface side. As another method, Patent Literature 2 has disclosed the method to form an emitter layer using the ion implantation method.

### CITATION LIST

### Patent Literatures

Patent Literature 1: Japanese Patent Application Laid-open No. 2010-56465
Patent Literature 2: Japanese Patent Application Laid-open No. 2013-128095

### SUMMARY

### Technical Problem

However, in the solar cell forming method described in Patent Literature 1, the area for diffusing boron needs to be increased in order to facilitate the alignment between the impurity diffusion region where boron is diffused, and a designing mask pattern for a metal electrode. In a high-concentration impurity diffusion region, the passivation effect on minority carriers, which contribute to power generation due to the field effect, on the junction interface can be improved. Meanwhile, carriers generated by solar light within an impurity diffusion region recombine in the high-concentration impurity diffusion region, and do not contribute to photoelectric conversion.

There is a case where the width of the high-concentration impurity diffusion region is reduced in terms of obtaining the field-effect passivation effect on the junction interface, and reducing the ohmic contact resistance. In this case, a misalignment between the high-concentration impurity diffusion region and the metal electrode may occur. When the metal electrode is out of alignment with the high-concentration impurity diffusion region, the electrical resistance in the contact portion between the metal electrode and the silicon substrate, that is, the contact resistance is increased. This leads to a reduction in fill factor (FF). In a high-concentration impurity diffusion region that is not covered with a metal electrode, degradation of the photoelectric conversion properties occurs due to recombination of the carriers generated by solar light within an impurity diffusion region. That is, a decrease in power generation efficiency is caused due to a misalignment between the high-concentration impurity diffusion region and the metal electrode.

The present invention has been achieved to solve the above problems, and an object of the present invention is to provide a solar cell having a selective emitter structure and achieving improvement in alignment accuracy for an electrode relative to an impurity diffusion layer in which impurities are diffused in a high concentration.

### Solution to Problem

In order to solve the problems and achieve the object, there is provided a solar cell manufacturing method including: a first step of forming, on one surface of a first conductivity-type semiconductor substrate, a first doped layer in which second conductivity-type impurities are diffused in a first concentration, and a second doped layer in which the second conductivity-type impurities are diffused in a second concentration lower than the first concentration, where the second doped layer has surface roughness different from the first doped layer; and a second step of forming a metal electrode on the first doped layer to be electrically connected to the first doped layer, wherein at the second step, a position of the first doped layer is detected based on a difference in light reflectance between the first doped layer and the second doped layer, which results from a difference in surface roughness between the first doped layer and the second doped layer, and then the metal electrode is formed in alignment with a detected position of the first doped layer.

### Advantageous Effects of Invention

According to the present invention, an effect is obtained where it is possible to obtain a solar cell having a selective emitter structure and achieving improvement in alignment accuracy for an electrode relative to an impurity diffusion layer in which impurities are diffused in a high concentration.

### BRIEF DESCRIPTION OF DRAWINGS

FIG. 1 is a bottom view of a crystalline silicon solar cell according to a first embodiment of the present invention as viewed from the back surface side opposed to a light receiving surface.

FIG. 2 is a top view of the crystalline silicon solar cell according to the first embodiment of the present invention as viewed from a light receiving side.

FIG. 3 is a schematic cross-sectional view of the crystalline silicon solar cell according to the first embodiment of the present invention, and is a cross-sectional view taken along the line A-A′ in FIG. 1 and the line B-B′ in FIG. 2.

FIG. 4 is a diagram of the crystalline silicon solar cell according to the first embodiment of the present invention, which focuses on a positional relation among a high-concentration boron-doped layer, a first low-concentration boron-doped layer, and a second low-concentration boron-doped layer, and is a partially-cutaway perspective view on the back surface side of the crystalline silicon solar cell.

FIG. 5 is a cross-sectional view of relevant parts of the crystalline silicon solar cell according to the first embodiment of the present invention, which schematically illustrate an example of steps of manufacturing this solar cell.

FIG. 6 is a cross-sectional view of relevant parts of the crystalline silicon solar cell according to the first embodiment of the present invention, which schematically illustrate an example of the steps of manufacturing this solar cell.

FIG. 7 is a cross-sectional view of relevant parts of the crystalline silicon solar cell according to the first embodiment of the present invention, which schematically illustrate an example of the steps of manufacturing this solar cell.

FIG. 8 is a cross-sectional view of relevant parts of the crystalline silicon solar cell according to the first embodiment of the present invention, which schematically illustrate an example of the steps of manufacturing this solar cell.

FIG. 9 is a cross-sectional view of relevant parts of the crystalline silicon solar cell according to the first embodiment of the present invention, which schematically illustrate an example of the steps of manufacturing this solar cell.

FIG. 10 is a cross-sectional view of relevant parts of the crystalline silicon solar cell according to the first embodiment of the present invention, which schematically illustrate an example of the steps of manufacturing this solar cell.

FIG. 11 is a cross-sectional view of relevant parts of the crystalline silicon solar cell according to the first embodiment of the present invention, which schematically illustrate an example of the steps of manufacturing this solar cell.

FIG. 12 is a flowchart illustrating a manufacturing method of the crystalline silicon solar cell according to the first embodiment of the present invention.

FIG. 13 is a schematic cross-sectional view illustrating an ion implantation method in the first embodiment of the present invention.

FIG. 14 is a diagram illustrating an example of the shape of a selective emitter region in the first embodiment of the present invention, and is a bottom view of an n-type monocrystalline silicon substrate as viewed from the back surface side.

FIG. 15 is a diagram illustrating an example of the shape of a selective emitter region formed by the ion implantation method in the first embodiment of the present invention, and is a partially-cutaway perspective view on the back surface side of the n-type monocrystalline silicon substrate.

FIG. 16 is a diagram illustrating an example of the shape of a selective emitter region in the first embodiment of the present invention, and is a partially-cutaway perspective view on the back surface side of the n-type monocrystalline silicon substrate.

FIG. 17 is a schematic cross-sectional view illustrating a dopant-paste printing method in a second embodiment of the present invention.

FIG. 18 is a diagram illustrating an example of the shape of a selective emitter region formed by the dopant-paste printing method in the second embodiment of the present invention, and is a partially-cutaway perspective view on the back surface side of the n-type monocrystalline silicon substrate.

FIG. 19 is a diagram illustrating an example of the shape of a selective emitter region in the second embodiment of the present invention, and is a partially-cutaway perspective view on the back surface side of the n-type monocrystalline silicon substrate.

FIG. 20 is a schematic cross-sectional view of a crystalline silicon solar cell according to a third embodiment of the present invention.

FIG. 21 is a cross-sectional view of relevant parts of the crystalline silicon solar cell according to the third embodiment of the present invention, which schematically illustrate an example of steps of manufacturing this solar cell.

FIG. 22 is a cross-sectional view of relevant parts of the crystalline silicon solar cell according to the third embodiment of the present invention, which schematically illustrate an example of the steps of manufacturing this solar cell.

FIG. 23 is a cross-sectional view of relevant parts of the crystalline silicon solar cell according to the third embodiment of the present invention, which schematically illustrate an example of the steps of manufacturing this solar cell.

FIG. 24 is a cross-sectional view of relevant parts of the crystalline silicon solar cell according to the third embodiment of the present invention, which schematically illustrate an example of the steps of manufacturing this solar cell.

FIG. 25 is a flowchart illustrating a manufacturing method of a crystalline silicon solar cell according to a fourth embodiment of the present invention.

FIG. 26 is a cross-sectional view of relevant parts of the crystalline silicon solar cell according to the fourth embodiment of the present invention, which schematically illustrate an example of steps of manufacturing this solar cell.

FIG. 27 is a cross-sectional view of relevant parts of the crystalline silicon solar cell according to the fourth embodiment of the present invention, which schematically illustrate an example of the steps of manufacturing this solar cell.

FIG. 28 is a cross-sectional view of relevant parts of the crystalline silicon solar cell according to the fourth embodiment of the present invention, which schematically illustrate an example of the steps of manufacturing this solar cell.

FIG. 29 is an enlarged schematic cross-sectional view illustrating a p-type impurity-doped layer of the crystalline silicon solar cell according to the fourth embodiment of the present invention.

### DESCRIPTION OF EMBODIMENTS

A solar cell manufacturing method and a solar cell according to embodiments of the present invention will be described below in detail with reference to the accompanying drawings. The embodiments below are not intended to limit the present invention. In the drawings described below, the scale of each member is sometimes different from the actual scale for the sake of easy understanding. The scale is also different between the drawings. Hatching may be added even in a plan view for the ease of viewing the diagram.

### First Embodiment

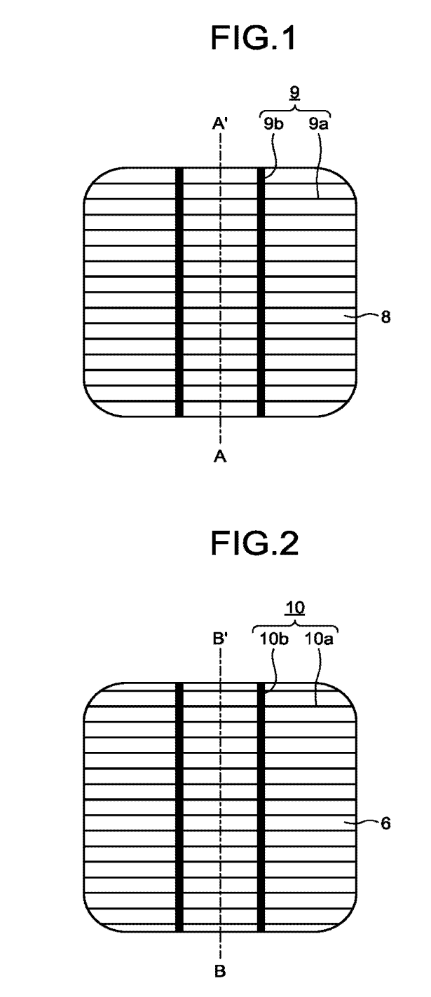

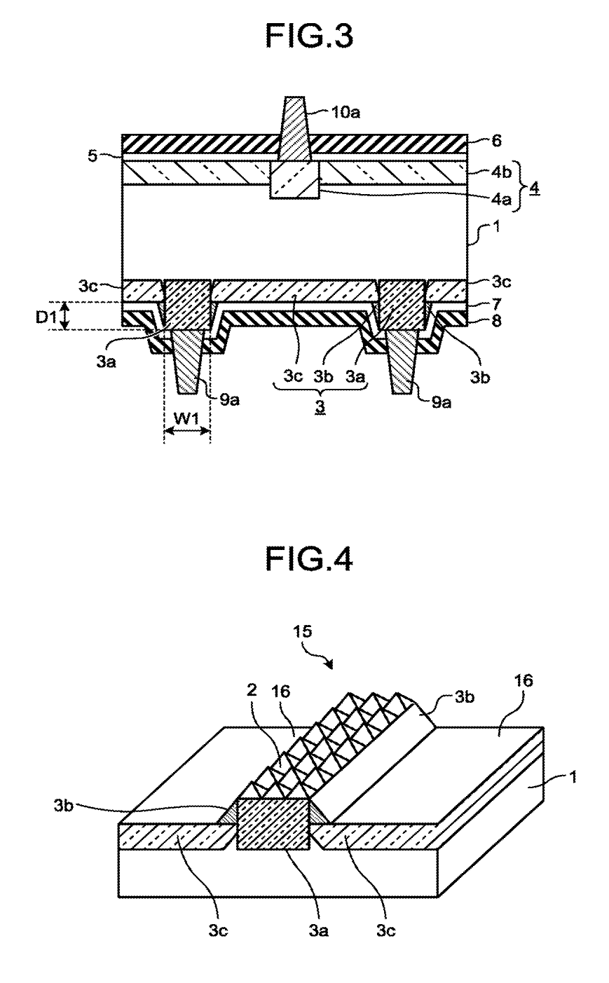

FIG. 1 is a bottom view of a crystalline silicon solar cell according to a first embodiment of the present invention as viewed from a back surface side opposed to the light receiving surface. FIG. 2 is a top view of the crystalline silicon solar cell according to the first embodiment of the present invention as viewed from a light receiving surface side. FIG. 3 is a schematic cross-sectional view of the crystalline silicon solar cell according to the first embodiment of the present invention, and is a cross-sectional view taken along the line A-A′ in FIG. 1 and the line B-B′ in FIG. 2. The position of the line B-B′ in FIG. 2 corresponds to the position of the line A-A′ in FIG. 1 on the plane of the crystalline silicon solar cell.

The crystalline silicon solar cell according to the first embodiment includes an n-type monocrystalline silicon substrate 1 that is a crystalline silicon substrate, a p-type impurity-doped layer 3 that is a p-type doped layer, an n-type impurity-doped layer 4 that is an n-type doped layer, a light-receiving-surface silicon oxide film (SiO₂ film) 5 and a light-receiving-surface silicon nitride film (SiN film) 6, each of which is a light-receiving-surface passivation film, a back-surface silicon oxide film (SiO₂ film) 7 and a back-surface silicon nitride film (SiN film) 8, each of which is a back-surface passivation film, a back-surface electrode 9 that is a metal electrode, and a light-receiving-surface electrode 10 that is a metal electrode.

The crystalline silicon solar cell according to the first embodiment includes a crystalline silicon substrate. Examples of the crystalline silicon substrate include a monocrystalline silicon substrate and a polycrystalline silicon substrate. Particularly, a monocrystalline silicon substrate, in which the silicon (100) plane is formed on the surface, that is, on the main surface, is preferable. It is sufficient that as a crystalline silicon substrate, a silicon substrate having p-type conductivity is used, or a silicon substrate having n-type conductivity is used. In the first embodiment, a case is described in which the n-type monocrystalline silicon substrate 1 is used. Even in the case of using a silicon substrate having p-type conductivity, individual members described below can still be used in the same manner.

The p-type impurity-doped layer 3 that is a doped layer, in which boron is diffused, is formed over the surface layer on the back surface side of the n-type monocrystalline silicon substrate 1, which is opposed to the light receiving surface that is a light-incident surface. A p-n junction is thereby formed. Further, the back-surface silicon oxide film 7 and the back-surface silicon nitride film 8, each of which is a back-surface passivation film made of an insulating film, are formed sequentially on the back surface of the n-type monocrystalline silicon substrate 1 on which the p-type impurity-doped layer 3 has been formed.

The p-type impurity-doped layer 3 includes a high-concentration boron-doped layer 3a, a first low-concentration boron-doped layer 3b, and a second low-concentration boron-doped layer 3c. In the high-concentration boron-doped layer 3a, boron is diffused in a relatively higher concentration compared to the first low-concentration boron-doped layer 3b and the second low-concentration boron-doped layer 3c. That is, in the first low-concentration boron-doped layer 3b and the second low-concentration boron-doped layer 3c, boron is diffused in a relatively lower concentration compared to the high-concentration boron-doped layer 3a. In the second low-concentration boron-doped layer 3c, boron is diffused in a concentration equivalent to, or relatively lower than, the first low-concentration boron-doped layer 3b.

FIG. 4 is a diagram of the crystalline silicon solar cell according to the first embodiment of the present invention, which focuses on the positional relation among the high-concentration boron-doped layer 3a, the first low-concentration boron-doped layer 3b, and the second low-concentration boron-doped layer 3c. FIG. 4 is a partially-cutaway perspective view on the back surface side of the crystalline silicon solar cell. In FIG. 4, illustrations of members are omitted excluding the n-type monocrystalline silicon substrate 1, the high-concentration boron-doped layer 3a, the first low-concentration boron-doped layer 3b, and the second low-concentration boron-doped layer 3c.

On the back surface of the n-type monocrystalline silicon substrate 1, the high-concentration boron-doped layer 3a is formed in a surface-layer region of a protruding portion 15 that is a first protruding portion that protrudes into a comb shape. On the back surface of the n-type monocrystalline silicon substrate 1, the second low-concentration boron-doped layer 3c is formed in a surface-layer region of a groove-opening portion 16 that is a first groove-opening portion other than the region of the protruding portion 15 that protrudes into a comb shape. The first low-concentration boron-doped layer 3b is formed adjacent to the protruding portion 15 in a region between the second low-concentration boron-doped layer 3c and the side of the protruding portion 15.

Further, a textured structure made of minute irregularities 2 is formed on the light-incident surface of the n-type monocrystalline silicon substrate 1, that is, the light receiving surface, and on the surface of the high-concentration boron-doped layer 3a, and the surface of the first low-concentration boron-doped layer 3b adjacent to the high-concentration boron-doped layer 3a. The textured structure formed on the light receiving surface of the n-type monocrystalline silicon substrate 1 is a structure that increases the area of absorbing external light on the light receiving surface, that reduces the light reflectance on the light receiving surface, and that traps the light.

A plurality of long and thin back-surface finger electrodes 9a are provided parallel to each other on the back surface side of the n-type monocrystalline silicon substrate 1. Back-surface bus electrodes 9b that are electrically continuous with these back-surface finger electrodes 9a are provided so as to be perpendicular to the back-surface finger electrodes 9a. The back-surface finger electrodes 9a, and the back-surface bus electrodes 9b are formed on the high-concentration boron-doped layer 3a. That is, the back-surface finger electrodes 9a, and the back-surface bus electrodes 9b are electrically connected at their bottom portion to the high-concentration boron-doped layer 3a. The back-surface finger electrodes 9a, and the back-surface bus electrodes 9b are connected to the high-concentration boron-doped layer 3a by passing completely through the back-surface silicon oxide film 7 and the back-surface silicon nitride film 8. The back-surface finger electrode 9a, and the back-surface bus electrode 9b are formed on the high-concentration boron-doped layer 3a without extending past the edges of the high-concentration boron-doped layer 3a.

As an example, each of the back-surface finger electrodes 9a has a height of approximately 10 μm to 100 μm, and a width of approximately 50 μm to 200 μm. The back-surface finger electrodes 9a are provided parallel to each other with the spacing of approximately 2 mm, and collect electricity generated within the crystalline silicon solar cell. As an example, each of the back-surface bus electrodes 9b has a width of approximately 500 μm to 2000 μm. Two to four back-surface bus electrodes 9b are provided per crystalline silicon solar cell, and extract electricity collected by the back-surface finger electrodes 9a to the outside. The back-surface finger electrode 9a, and the back-surface bus electrode 9b constitute the back-surface electrode 9 that is a metal electrode. The back-surface finger electrode 9a, and the back-surface bus electrode 9b are made of aluminum, or mixed material of aluminum and silver.

The n-type impurity-doped layer 4 that is a doped layer, in which phosphorus is diffused, is formed over the surface layer on the light receiving surface side of the n-type monocrystalline silicon substrate 1. The n-type impurity-doped layer 4 is provided with an n+ layer that includes impurities in a higher concentration than the n-type monocrystalline silicon substrate 1. Further, the light-receiving-surface silicon oxide film 5 and the light-receiving-surface silicon nitride film 6, each of which is a light-receiving-surface passivation film made of an insulating film, are formed sequentially on the light receiving surface of the n-type monocrystalline silicon substrate 1 on which the n-type impurity-doped layer 4 has been formed.

The n-type impurity-doped layer 4 is formed of a high-concentration phosphorus-doped layer 4a in which phosphorous is diffused in a relatively higher concentration, and a low-concentration phosphorus-doped layer 4b in which phosphorous is diffused in a relatively lower concentration. The high-concentration phosphorus-doped layer 4a is formed into a comb shape on the light receiving surface of the n-type monocrystalline silicon substrate 1. The low-concentration phosphorus-doped layer 4b is formed entirely on the light receiving surface of the n-type monocrystalline silicon substrate 1, except on the region where the high-concentration phosphorus-doped layer 4a is formed.

A plurality of long and thin light-receiving-surface finger electrodes 10a are provided parallel to each other on the light receiving surface side of the n-type monocrystalline silicon substrate 1. Light-receiving-surface bus electrodes 10b that are electrically continuous with these light-receiving-surface finger electrodes 10a are provided so as to be perpendicular to the light-receiving-surface finger electrodes 10a. The light-receiving-surface finger electrodes 10a, and the light-receiving-surface bus electrodes 10b are formed on the high-concentration phosphorus-doped layer 4a. That is, the light-receiving-surface finger electrodes 10a, and the light-receiving-surface bus electrodes 10b are electrically connected at their bottom portion to the high-concentration phosphorus-doped layer 4a. The light-receiving-surface finger electrodes 10a, and the light-receiving-surface bus electrodes 10b are connected to the high-concentration phosphorus-doped layer 4a by passing completely through the light-receiving-surface silicon oxide film 5 and the light-receiving-surface silicon nitride film 6.

As an example, each of the light-receiving-surface finger electrodes 10a has a height of approximately μm to 100 μm, and a width of approximately 50 μm to 200 μm. The light-receiving-surface finger electrodes 10a are provided parallel to each other with the spacing of approximately 2 mm, and collect electricity generated within the crystalline silicon solar cell. As an example, each of the light-receiving-surface bus electrodes 10b has a width of approximately 500 μm to 2000 μm. Two to four light-receiving-surface bus electrodes 10b are provided per crystalline silicon solar cell, and extract electricity collected by the light-receiving-surface finger electrodes 10a to the outside. The light-receiving-surface finger electrode 10a, and the light-receiving-surface bus electrode 10b constitute the light-receiving-surface electrode 10 that is a metal electrode. The light-receiving-surface finger electrode 10a, and the light-receiving-surface bus electrode 10b are made of silver material.

In a p-type doped layer, a large amount of impurities such as boron is contained in the silicon. The p-type doped layer has a profile that contains impurities distributed from the surface to the deep position, and therefore has a greater amount of light absorption than an n-type doped layer. Accordingly, in the case where the p-type doped layer is provided on the surface of the light receiving surface side, this increases the amount of light to be absorbed relative to the entire amount of light incident to the crystalline silicon solar cell, and decreases the amount of light to be used for photoelectric conversion, as compared to the case where the n-type doped layer is provided on the surface of the light receiving surface side. Therefore, in the case where an n-type monocrystalline silicon substrate is used as described for the crystalline silicon solar cell in the first embodiment, a p-type doped layer is provided on the back surface side of the substrate. This can increase the amount of light to be used for photoelectric conversion relative to the entire amount of light incident to the crystalline silicon solar cell.

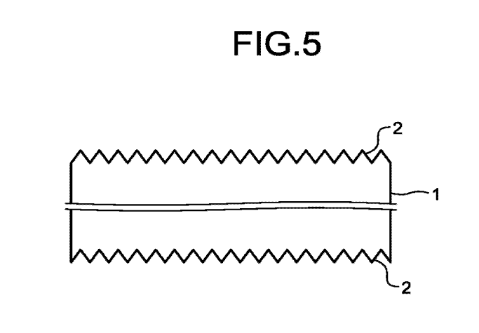

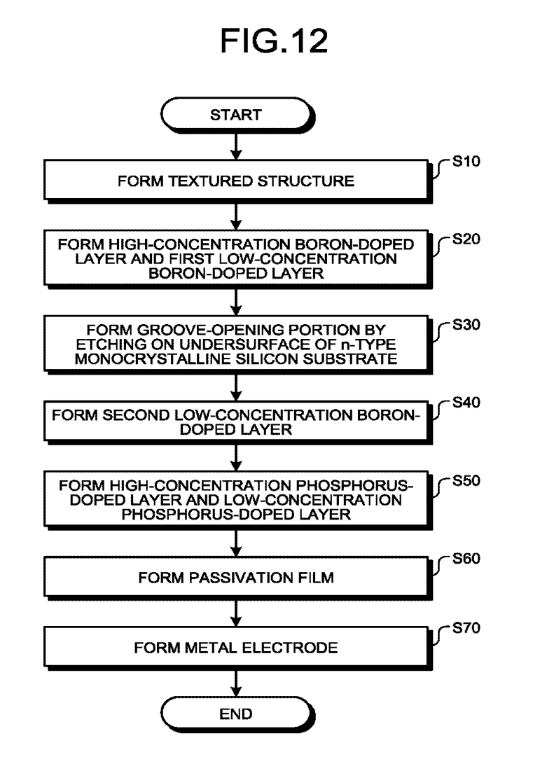

Next, the crystalline silicon solar cell according to the first embodiment is described in detail through explaining a manufacturing method of the crystalline silicon solar cell with reference to the drawings. FIGS. 5 to 11 are cross-sectional views of the relevant parts of the crystalline silicon solar cell according to the first embodiment of the present invention, which schematically illustrate an example of the steps of manufacturing this solar cell. FIG. 12 is a flowchart illustrating the manufacturing method of the crystalline silicon solar cell according to the first embodiment of the present invention.

First, the n-type monocrystalline silicon substrate 1 is prepared. The n-type monocrystalline silicon substrate 1 is manufactured by slicing a silicon ingot grown from molten silicon with a wire saw. Therefore, it is preferable to use the n-type monocrystalline silicon substrate 1 from which slicing damage caused by slicing a silicon ingot has been removed.

As an example of the slicing damage removing method, etching is performed using mix acid of a hydrogen fluoride solution (HF) and nitric acid (HNO₃), or using an alkaline aqueous solution, typically, a sodium hydroxide (NaOH) aqueous solution. As the slicing damage removing method, a dry-cleaning method using plasma, ultraviolet (UV), ozone, or the like, a heat-treatment method, or other methods can be appropriately used according to the state of contamination on a silicon substrate. While the shape and size of the n-type monocrystalline silicon substrate 1 are not particularly limited, it is preferable to have a thickness ranging from 80 μm to 400 μm, and a specific resistance of 1.0 Ω·cm to 10.0 Ω·cm, for example. Further, it is preferable that the main surface, that is, the surface sliced from a silicon ingot has a (100) plane orientation.

First, at Step S10, a step of forming a textured structure made of the minute irregularities 2 on both surfaces of the n-type monocrystalline silicon substrate 1 is performed as illustrated in FIG. 5. The textured structure is provided to trap the light incident to the n-type monocrystalline silicon substrate 1 so as to improve the light usage efficiency. The textured structure is formed with the minute irregularities 2, which are sized to have an average interval of 1 μm or greater, and less than 10 μm, and an average height of less than 10 μm. Square pyramid-shaped minute irregularities 2 are formed mainly by the silicon (111) plane. The interval of the irregularities is the spacing for forming the irregularities in the planar direction of the n-type monocrystalline silicon substrate 1, and is defined as the distance between the peaks of the adjacent minute irregularities 2.

The etching conditions to form the textured structure as described above are adjusted such that on both surfaces of the n-type monocrystalline silicon substrate 1, the etching speed is fastest on the (100) plane, followed by the (110) plane, and slowest on the (111) plane. As an etching method to form the textured structure, anisotropic etching is performed with a solution obtained by adding an additive that promotes the anisotropic etching, such as isopropyl alcohol (IPA), to a low-concentration alkaline solution, for example, a low-concentration alkaline solution containing less than 10 wt % sodium hydroxide or potassium hydroxide. That is, the textured structure can be formed by performing wet etching using an alkaline solution on both surfaces of the n-type monocrystalline silicon substrate 1. In this case, it is also possible that wet etching is performed on each of the surfaces of the n-type monocrystalline silicon substrate 1. However, it is preferable to soak the n-type monocrystalline silicon substrate 1 in an alkaline solution in terms of productivity.

After the textured structure is formed, the surface of the n-type monocrystalline silicon substrate 1 is cleaned with functional water such as acidic water, ozone water, or carbonated water to such a degree that organic contamination, metal contamination, and particle contamination on the surface of the n-type monocrystalline silicon substrate 1 are sufficiently reduced to the practical level.

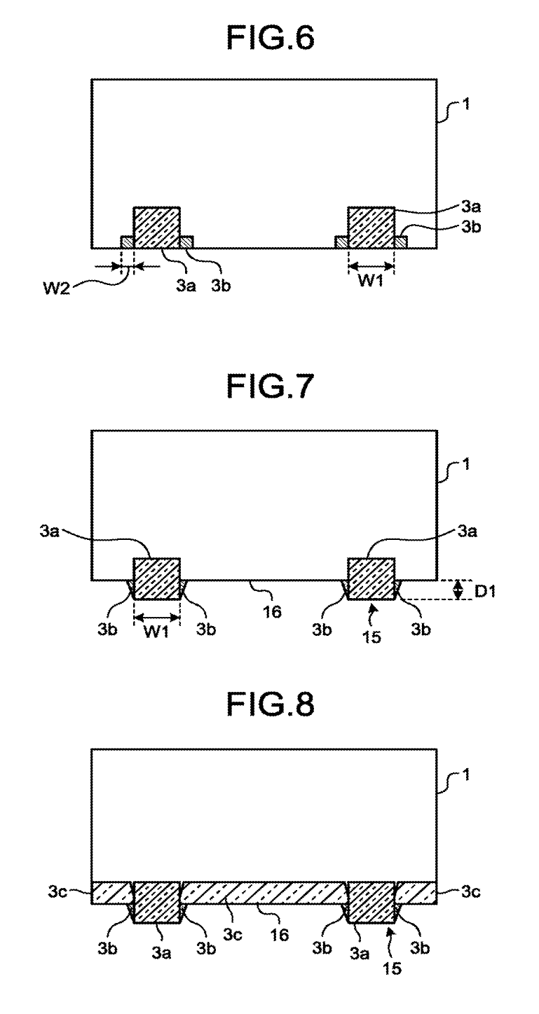

Next, at Step S20, the high-concentration boron-doped layer 3a that becomes a selective emitter region, and the first low-concentration boron-doped layer 3b are formed on the back surface side of the n-type monocrystalline silicon substrate 1 as illustrated in FIG. 6. The back surface of the n-type monocrystalline silicon substrate 1 is a surface that becomes a back surface of the crystalline silicon solar cell. In the first embodiment, the high-concentration boron-doped layer 3a that becomes a selective emitter region is formed by using an ion implantation method. In FIGS. 6 to 11, illustrations of the minute irregularities 2 are omitted.

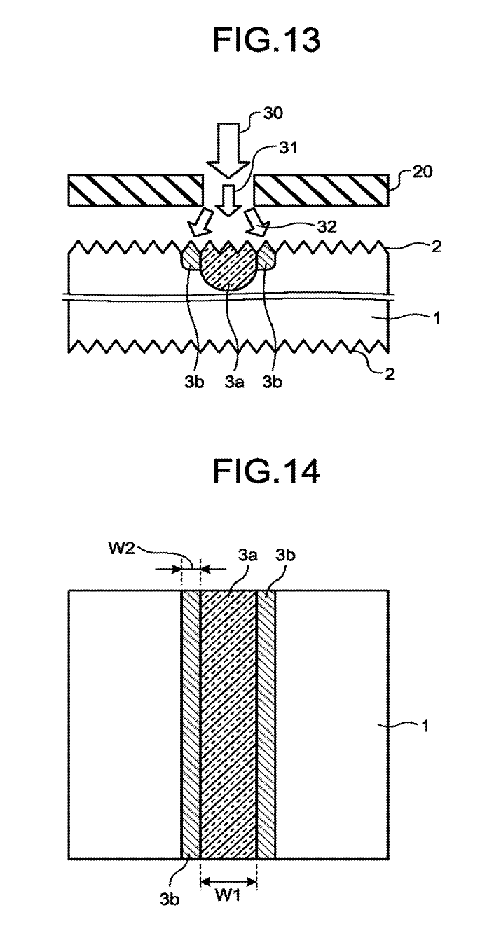

In the case where a selective emitter region is formed by the ion implantation method, a boron ion beam 30, in which boron having a mass number of 11 has been ionized, is implanted vertically onto the back surface of the n-type monocrystalline silicon substrate 1 by using a mask 20 as illustrated in FIG. 13. The selective emitter region can thereby be formed. While boron having a mass number of 10, and boron having a mass number of 11 are available, the boron having a mass number of 11 is commonly used. The mask 20, when it is aligned on the back surface of the n-type monocrystalline silicon substrate 1, is provided with an opening in a predetermined pattern at the position corresponding to the region, where a selective emitter region is formed, on the back surface of the n-type monocrystalline silicon substrate 1. FIG. 13 is a schematic cross-sectional view illustrating the ion implantation method in the first embodiment of the present invention.

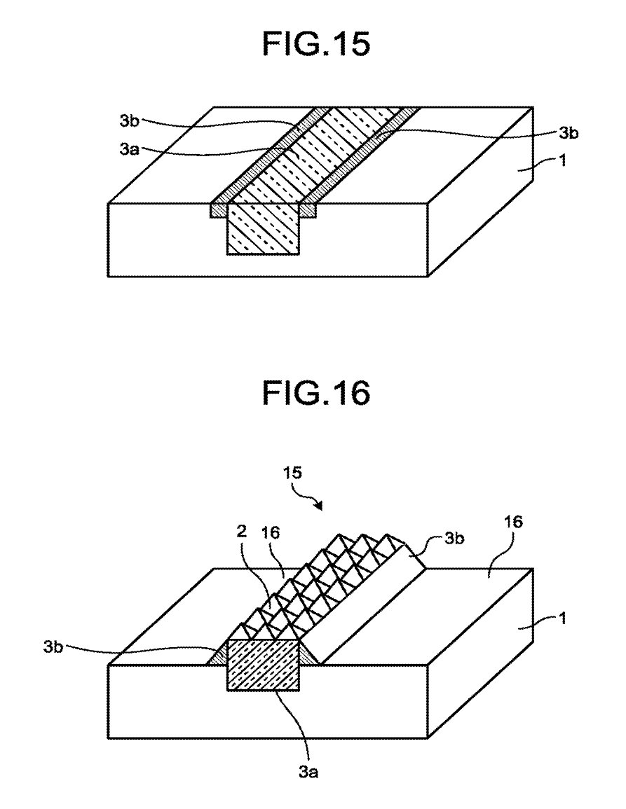

However, when the ion implantation method is used, the high-concentration boron-doped layer 3a, and the first low-concentration boron doped layer 3b are formed on the back surface of the n-type monocrystalline silicon substrate 1 as illustrated in FIGS. 13 to 15 under the conditions of the boron ion beam 30, or the conditions such as a distance between the locations of the n-type monocrystalline silicon substrate 1 and the mask 20. FIG. 14 is a diagram illustrating an example of the shape of a selective emitter region in the first embodiment of the present invention. FIG. 14 is a bottom view of the n-type monocrystalline silicon substrate 1 as viewed from the back surface side. FIG. 15 is a diagram illustrating an example of the shape of a selective emitter region formed by the ion implantation method in the first embodiment of the present invention. FIG. 15 is a partially-cutaway perspective view on the back surface side of the n-type monocrystalline silicon substrate 1.

The boron ion beam 30, having been irradiated on the back surface of the n-type monocrystalline silicon substrate 1 through the mask 20, is distributed into a straight component 31 that is irradiated vertically on the back surface of the n-type monocrystalline silicon substrate 1, and into a scattering component 32 that spreads outward from the straight component 31, and is irradiated on the back surface of the n-type monocrystalline silicon substrate 1. The region, onto which boron ions of the straight component 31 have been implanted, becomes the high-concentration boron-doped layer 3a in which boron is doped in a first concentration. The region, onto which boron ions of the scattering component 32 have been implanted, becomes the first low-concentration boron-doped layer 3b in which boron is doped in a second concentration lower than the first concentration. The first low-concentration boron-doped layer 3b is smaller in the amount of boron-ion implantation, and is therefore shallower, than the high-concentration boron-doped layer 3a. “First doped layer” in the claims corresponds to the high-concentration boron-doped layer 3a.

It is preferable that the high-concentration boron-doped layer 3a has a width W1 that ranges from 50 μm to 500 μm. When the width W1 is less than 50 μm, it is difficult for an electrode to be overlaid on the high-concentration boron-doped layer 3a. When the width W1 is greater than 500 μm, this increases the amount of the light to be absorbed into the high-concentration boron-doped layer 3a, relative to the amount of light that has passed through the p-n junction from the n-type monocrystalline silicon substrate 1, and entered into the high-concentration boron-doped layer 3a. In this case, the amount of light that reflects off the back surface finger electrode 9a, and the back surface bus electrode 9b, and returns to the p-n junction, is reduced. This reduces the amount of light that contributes to photoelectric conversion.

A width W2 of the first low-concentration boron-doped layer 3b is approximately one-tenth of the width W1 of the high-concentration boron-doped layer 3a, although it depends on the conditions of the boron ion beam 30, or the conditions such as a distance between the locations of the n-type monocrystalline silicon substrate 1 and the mask 20.

Next, high-temperature annealing treatment is performed at a temperature of approximately 900° C. or higher in order to electrically activate the boron implanted onto the n-type monocrystalline silicon substrate 1. As the high-temperature annealing treatment, a lamp annealing method, a laser annealing method, or a furnace annealing method is commonly used. In the solar-cell manufacturing, from the viewpoint of productivity, it is preferable to perform heat treatment by means of furnace annealing in which a plurality of solar cells can be simultaneously processed together. In the first embodiment, high-temperature annealing is performed using a horizontal diffusion furnace. In the annealing treatment conditions, the maximum temperature, the treatment time, and the atmosphere are changed to adjust the concentration of boron, mainly having a mass number of 11, in the high-concentration boron-doped layer 3a formed on the back surface of the n-type monocrystalline silicon substrate 1, such that the concentration becomes 1.0×10²⁰/cm³ or greater, and 1.0×10²¹/cm³ or less.

The high-concentration boron-doped layer 3a is formed immediately below the back surface finger electrode 9a and the back surface bus electrode 9b. Therefore, the high-concentration boron-doped layer 3a is formed, while its width and surface area on the back surface of the n-type monocrystalline silicon substrate 1 is adjusted according to the accuracy of overlaying the electrode on the high-concentration boron-doped layer 3a at the time of forming the back-surface finger electrode 9a and the back-surface bus electrode 9b which are described later. That is, the width and surface area of the high-concentration boron-doped layer 3a on the back surface of the n-type monocrystalline silicon substrate 1 are adjusted to be small to the extent that the electrode does not extend past the edges of the high-concentration boron-doped layer 3a according to the accuracy of overlaying the electrode on the high-concentration boron-doped layer 3a.

Next, at Step S30, the back surface of the n-type monocrystalline silicon substrate 1 is etched to form the groove-opening portion 16 as illustrated in FIG. 7. That is, selective etching is performed on the back surface of the n-type monocrystalline silicon substrate 1 by using the high-concentration boron-doped layer 3a as a mask. In the first embodiment, an etching method is used, in which only one side, that is the back surface side of the n-type monocrystalline silicon substrate 1, is etched. It is also possible that a protective film such as an oxide (SiO₂) film or a nitride (SiN) film is formed on the light receiving surface of the n-type monocrystalline silicon substrate 1 to etch the entire surface of the n-type monocrystalline silicon substrate 1. The selective etching is performed by using an alkaline solution as an etching solution. As an alkaline solution, potassium hydroxide (KOH), tetramethylammonium hydroxide (TMAH), ethylene diamine pyrocatechol (EDP), or other types of solutions can be used.

In the wet etching treatment using an alkaline solution, it is preferable that the temperature of the etching solution is approximately 40° C. to 100° C., and the etching time is about 1 to 30 minutes. The etching amount depends on the boron surface-impurity concentration on the back surface of the n-type monocrystalline silicon substrate 1. The etching rate sharply decreases as the concentration becomes 1.0×10²⁰/cm³ or greater. Therefore, the etching rate is fastest on the n-type monocrystalline silicon substrate 1, followed by the first low-concentration boron-doped layer 3b, and slowest on the high-concentration boron-doped layer 3a. Therefore, the high-concentration boron-doped layer 3a can be used as an etching mask.

After the back surface of the n-type monocrystalline silicon substrate 1 is etched, the region of the high-concentration boron-doped layer 3a becomes the protruding portion 15 that protrudes from the other region on the etched back surface of the n-type monocrystalline silicon substrate 1 as illustrated in FIGS. 7 and 16. FIG. 16 is a diagram illustrating an example of the shape of a selective emitter region in the first embodiment of the present invention. FIG. 16 is a partially-cutaway perspective view on the back surface side of the n-type monocrystalline silicon substrate 1. On the etched back surface side of the n-type monocrystalline silicon substrate 1, the first low-concentration boron-doped layer 3b has a height that decreases as it is more distanced from the region of the high-concentration boron-doped layer 3a. The region, where the high-concentration boron-doped layer 3a is not formed, becomes the groove-opening portion 16. The groove-opening portion 16 includes a region, which is not interposed between the adjacent protruding portions 15, at the outer peripheral edge of the back surface of the n-type monocrystalline silicon substrate 1. Therefore, the groove-opening portion 16 refers to a surface, which is formed in the boron-undoped region by means of etching, and which is lower than the protruding portion 15.

In the first embodiment, a depth D1 of the groove-opening portion 16, which is a difference in height between the surface of the high-concentration boron-doped layer 3a, and the etched back surface of the n-type monocrystalline silicon substrate 1, is adjusted so as to become approximately 1 μm to 10 μm. That is, the depth D1 of the groove-opening portion 16 is a difference in height between the top surface of the high-concentration boron-doped layer 3a and the back surface of the n-type monocrystalline silicon substrate 1 in the height direction of the n-type monocrystalline silicon substrate 1. The minute irregularities 2 are formed and sized to have an average height of 1 μm to 10 μm. Therefore, the minute irregularities 2 are etched in the region other than the high-concentration boron-doped layer 3a by adjusting the depth D1 of the groove-opening portion 16 so as to become approximately 1 μm to 10 μm, while being greater than the height of the formed minute irregularities 2.

When the boron surface-impurity concentration in the high-concentration boron-doped layer 3a is equal to or greater than 1.0×10²⁰/cm³, the etching rate decreases so sharply that the high-concentration boron-doped layer 3a is hardly etched. Therefore, as illustrated in FIG. 16, even after the etching, the minute irregularities 2 of the textured structure still remain on the surface of the high-concentration boron-doped layer 3a. Accordingly, after the etching, the average roughness on the top surface of the high-concentration boron-doped layer 3a falls within the range of 1 μm or greater, and less than 10 μm. After the etching, the minute irregularities 2 remain on the top surface of the high-concentration boron-doped layer 3a, and therefore the top surface thereof is constituted mainly by the silicon (111) plane.

Meanwhile, in the first low-concentration boron-doped layer 3b, the minute irregularities 2 of the textured structure are partially processed and removed by etching. Therefore, the first low-concentration boron-doped layer 3b is in a state in which the silicon (100) plane, (111) plane, (110) plane, and (311) plane are present. A region, onto which boron is not implanted, on the back surface of the n-type monocrystalline silicon substrate 1 prior to the etching, that is, the bottom surface of the groove-opening portion 16 is removed more by etching at the fastest etching rate, resulting in a surface on which the minute irregularities 2 are more significantly processed. Therefore, after the etching, the surface roughness on the top surface of the high-concentration boron-doped layer 3a, that is, the average roughness is different from the surface roughness on the bottom surface of the groove-opening portion 16. The top surface of the high-concentration boron-doped layer 3a has greater surface roughness. In the first embodiment, the case has been described in which etching is performed with an alkaline solution. However, it is also possible that an etching method with an acidic solution, a dry etching method, or an etching paste method is used as isotropic etching in combination with the anisotropic etching.

Next, at Step S40, the second low-concentration boron-doped layer 3c is formed as illustrated in FIG. 8. By implanting boron ions onto the entire surface on the back surface of the n-type monocrystalline silicon substrate 1, the second low-concentration boron-doped layer 3c is formed over the surface layer of the bottom surface of the groove-opening portion 16, where the high-concentration boron-doped layer 3a and the first low-concentration boron-doped layer 3b are not formed. Depending on the configuration of the crystalline silicon solar cell, it may also be possible that ion implantation is performed using a mask in such a manner as to form an undoped region, where boron is not doped, on only the outer peripheral portion of the back surface of the n-type monocrystalline silicon substrate 1.

The second low-concentration boron-doped layer 3c is implanted with boron in a concentration equal to, or lower than, the first low-concentration boron-doped layer 3b. At this time, boron is also implanted onto the region immediately below the first low-concentration boron-doped layer 3b, and therefore the second low-concentration boron-doped layer 3c extends into the region immediately below the first low-concentration boron-doped layer 3b. Accordingly, the high-concentration boron-doped layer 3a, the first low-concentration boron-doped layer 3b, and the second low-concentration boron-doped layer 3c are electrically and mechanically connected to each other. “Second doped layer” in the claims corresponds to the second low-concentration boron-doped layer 3c.

Next, high-temperature annealing treatment is performed at a temperature of 900° C. or higher in order to electrically activate the boron implanted onto the n-type monocrystalline silicon substrate 1. As the high-temperature annealing treatment, a lamp annealing method, a laser annealing method, or a furnace annealing method is commonly used. In the annealing treatment conditions, the maximum temperature, the treatment time, and the atmosphere are changed to adjust the concentration of boron, mainly having a mass number of 11, in the second low-concentration boron-doped layer 3c formed on the back surface of the n-type monocrystalline silicon substrate 1, such that the concentration becomes 5.0×10¹⁸/cm³ or greater, and 5.0×10¹⁹/cm³ or less. When the boron concentration in the second low-concentration boron-doped layer 3c is less than 5.0×10¹⁸/cm³, the conductivity of the second low-concentration boron-doped layer 3c may sometimes be insufficient. When the boron concentration in the second low-concentration boron-doped layer 3c is greater than 5.0×10¹⁹/cm³, this may increase the recombination of carriers in the second low-concentration boron-doped layer 3c, which are generated by photoelectric conversion within the crystalline silicon solar cell, and may therefore decrease the photoelectric conversion efficiency.

In the first embodiment, the case has been described in which high-temperature annealing treatment is performed at a temperature of approximately 900° C. or higher in order to electrically activate the boron in the high-concentration boron-doped layer 3a and the first low-concentration boron-doped layer 3b, and the groove-opening portion 16 is formed by etching. It is also possible to use the following method as an alternative method for electrically activating the boron in the high-concentration boron-doped layer 3a and the first low-concentration boron-doped layer 3b. That is, first the high-concentration boron-doped layer 3a and the first low-concentration boron-doped layer 3b are formed, and thereafter the groove-opening portion 16 is formed by etching without electrically activating the boron. After the second low-concentration boron-doped layer 3c is formed, the annealing treatment is performed in order to electrically activate the boron implanted onto the high-concentration boron-doped layer 3a, the first low-concentration boron-doped layer 3b, and the second low-concentration boron-doped layer 3c simultaneously.

It is also possible that the second low-concentration boron-doped layer 3c is formed by using a method to apply a boron-containing dopant paste, or an atmospheric pressure chemical vapor deposition (APCVD) method.

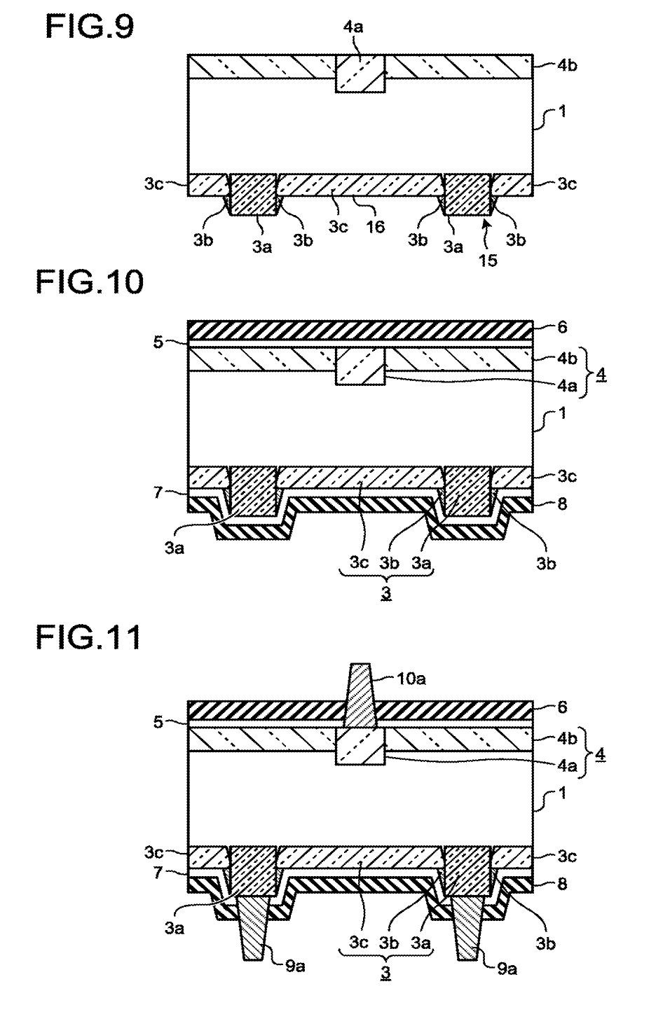

Next, at Step S50, the high-concentration phosphorus-doped layer 4a, and the low-concentration phosphorus-doped layer 4b are formed as illustrated in FIG. 9. That is, in the same manner as on the back surface side of the n-type monocrystalline silicon substrate 1, phosphorus ion beam in which phosphorus is ionized is irradiated on the light receiving surface side of the n-type monocrystalline silicon substrate 1 through a mask to form the high-concentration phosphorus-doped layer 4a. Further, the phosphorus ion beam is irradiated on the entire surface on the light receiving surface side of the n-type monocrystalline silicon substrate 1 to form the low-concentration phosphorus-doped layer 4b. Thereafter, high-temperature annealing treatment is performed at a temperature of approximately 900° C. or higher in order to electrically activate the phosphorus implanted onto the light receiving surface side of the n-type monocrystalline silicon substrate 1.

Next, at Step S60, a passivation film is formed on the light receiving surface side and the back surface side of the n-type monocrystalline silicon substrate 1 as illustrated in FIG. 10. That is, as illustrated in FIG. 10, as a back-surface passivation film, the back-surface silicon oxide film 7, and the back-surface silicon nitride film 8 are formed in the described order on the entire surface on the back surface of the n-type monocrystalline silicon substrate 1. Further, as illustrated in FIG. 10, as a light-receiving-surface passivation film, the light-receiving-surface silicon oxide film 5, and the light-receiving-surface silicon nitride film 6 are formed in the described order on the entire surface on the light receiving surface side of the n-type monocrystalline silicon substrate 1.

First, the back-surface silicon oxide film 7 is formed on the entire surface on the back surface side of the n-type monocrystalline silicon substrate 1. Therefore, the back-surface silicon oxide film 7 is formed so as to cover the high-concentration boron-doped layer 3a, the first low-concentration boron-doped layer 3b, and the second low-concentration boron-doped layer 3c. Further, the light-receiving-surface silicon oxide film 5 is formed on the entire surface on the light receiving surface side of the n-type monocrystalline silicon substrate 1. Therefore, the light-receiving-surface silicon oxide film 5 is formed so as to cover the high-concentration phosphorus-doped layer 4a and the low-concentration phosphorus-doped layer 4b.

The light-receiving-surface silicon oxide film 5 is formed by dry oxidation on the light receiving surface of the n-type monocrystalline silicon substrate 1. The back-surface silicon oxide film 7 is formed by dry oxidation on the back surface of the n-type monocrystalline silicon substrate 1. The dry oxidation can be performed by using a high-temperature electric furnace and high-purity oxygen. Preferably, the oxidation temperature is approximately 900° C. to 1200° C. The thickness of the light-receiving-surface silicon oxide film 5, and the back-surface silicon oxide film 7 ranges approximately between nm to 40 nm. The light-receiving-surface silicon oxide film 5, and the back-surface silicon oxide film 7 function as a passivation film on the surface of the n-type monocrystalline silicon substrate 1.

Subsequently to forming the light-receiving-surface silicon oxide film 5, and the back-surface silicon oxide film 7, the light-receiving-surface silicon nitride film 6, and the back-surface silicon nitride film 8 are formed as a passivation film on the light receiving surface side, and the back surface of the n-type monocrystalline silicon substrate 1, respectively, as illustrated in FIG. 10.

That is, as illustrated in FIG. 10, the back-surface silicon nitride film 8 is formed over the entire surface of the back-surface silicon oxide film 7. Further, the light-receiving-surface silicon nitride film 6 is formed over the entire surface of the light-receiving-surface silicon oxide film 5.

The light-receiving-surface silicon nitride film 6, and the back-surface silicon nitride film 8 are formed by using the plasma CVD method. As the film-forming conditions, silane gas (SiH₄), nitrogen gas (N₂), and ammonia gas (NH₃) are used as reaction gas, and the film-forming temperature is equal to or higher than 300° C. It is preferable for the light-receiving-surface silicon nitride film 6, and the back-surface silicon nitride film 8 to have a thickness that ranges approximately between 10 nm to 100 nm.

A silicon nitride film (SiN film) has a positive fixed charge. Therefore, the silicon nitride film (SiN film) can further improve the passivation effect particularly on the silicon interface on the n-type layer-side surface of a silicon substrate. That is, the back-surface silicon nitride film 8 can further improve the passivation effect on the back surface side of the n-type monocrystalline silicon substrate 1. Furthermore, a silicon nitride film (SiN film) can be used on the light receiving surface side as an anti-reflective film, in addition to improving the passivation effect. That is, the light-receiving-surface silicon nitride film 6 can be used as an anti-reflective film. It is also possible that as a passivation film for the silicon interface on the back surface side of the n-type monocrystalline silicon substrate 1, an aluminum oxide (Al₂O₃) film may be used, or a stacked film of the aluminum oxide (Al₂O₃) film and the silicon oxide film may be used.

It is preferable to perform cleaning of the silicon substrate 1 using a cleaning solution that includes concentrated sulfuric acid and a hydrogen peroxide solution, a cleaning solution that includes hydrochloric acid and a hydrogen peroxide solution, or a hydrofluoric acid solution, prior to the aforementioned annealing treatment for electrically activating the ionized impurities implanted onto the n-type monocrystalline silicon substrate 1, and prior to the step of performing the heat treatment on the n-type monocrystalline silicon substrate 1 at a high temperature, such as dry oxidation. By performing the cleaning in the manner as described above, organic contamination, metal contamination, and particle contamination on the surface and in the interior of the n-type monocrystalline silicon substrate 1 can be reduced sufficiently to the practical level. It is also possible that the cleaning with functional water such as ozone water or carbonated water is performed on the n-type monocrystalline silicon substrate 1. In this case, organic contamination, metal contamination, and particle contamination on the surface and in the interior of the n-type monocrystalline silicon substrate 1 can also be reduced sufficiently to the practical level.

Next, at Step S70, a metal electrode is formed on both surfaces of the n-type monocrystalline silicon substrate 1 as illustrated in FIG. 11. First, as illustrated in FIG. 11, the back surface electrode 9 that is a metal electrode is formed on the high-concentration boron-doped layer 3a on the back surface side of the n-type monocrystalline silicon substrate 1, and is electrically and mechanically joined to the high-concentration boron-doped layer 3a.

As a method for joining the back surface electrode 9 to the high-concentration boron-doped layer 3a, a conductive paste for forming an electrode, which is made of only aluminum (Al), or mixed material of aluminum (Al) and silver (Ag), is applied onto the high-concentration boron-doped layer 3a by screen printing, and is then fired at a high temperature of approximately 700° C. or higher. By this fire-through process, a metallic composition in the printed conductive paste, that is, aluminum (Al), or mixed material of aluminum (Al) and silver (Ag), breaks through the back-surface silicon nitride film 8 and the back-surface silicon oxide film 7, and is joined to the high-concentration boron-doped layer 3a.

Similarly to the back-surface electrode 9, as illustrated in FIG. 11, the light-receiving-surface electrode 10 that is a metal electrode is formed on the high-concentration phosphorus-doped layer 4a on the light receiving surface side of the n-type monocrystalline silicon substrate 1, and is electrically and mechanically joined to the high-concentration phosphorus-doped layer 4a. As a method for joining the light-receiving-surface electrode 10 to the high-concentration phosphorus-doped layer 4a, a conductive paste for forming an electrode, which is made of silver (Ag), is applied onto the high-concentration phosphorus-doped layer 4a by screen printing, and is then fired at a high temperature of approximately 700° C. or higher. By this fire-through process, a metallic composition in the printed conductive paste, that is, silver (Ag) breaks through the light-receiving-surface silicon nitride film 6, and the light-receiving-surface silicon oxide film 5, and is joined to the high-concentration phosphorus-doped layer 4a.

Each of the back-surface finger electrode 9a of the back-surface electrode 9, and the light-receiving-surface finger electrode 10a of the light-receiving-surface electrode 10, has a height of approximately 10 μm to 100 μm, and a width of approximately 50 μm to 200 μm, for example. A plurality of back-surface finger electrodes 9a, and a plurality of light-receiving-surface finger electrodes 10a are formed. Each of the back-surface bus electrode 9b of the back-surface electrode 9, and the light-receiving-surface bus electrode 10b of the light-receiving-surface electrode 10, has a width of approximately 500 μm to 2000 μm, for example. Two back-surface bus electrodes 9b and two light-receiving-surface bus electrodes 10b are formed.

There is described alignment when a conductive paste for forming the back-surface electrode 9 is applied onto the high-concentration boron-doped layer 3a by screen printing. At the time of forming the back-surface electrode 9, the minute irregularities 2 of the textured structure remain on the entire surface of the high-concentration boron-doped layer 3a. Meanwhile, on the surface of the first low-concentration boron-doped layer 3b, the minute irregularities 2 of the textured structure are partially processed and removed by etching. Therefore, the surface of the first low-concentration boron-doped layer 3b is in a state in which the silicon (100) plane, (111) plane, (110) plane, and (311) plane are present. The surface of the second low-concentration boron-doped layer 3c is the bottom surface of the groove-opening portion 16, on which the minute irregularities 2 are more significantly processed.

This results in a significant difference in light reflectance between the surface of the high-concentration boron-doped layer 3a with the minute irregularities 2 remaining on its entire surface, and the surface of the second low-concentration boron-doped layer 3c on which the minute irregularities 2 have been more significantly processed. That is, on the surface of the second low-concentration boron-doped layer 3c, the amount of regular reflection is greater, and therefore the regular reflectance is also greater, than the surface of the high-concentration boron-doped layer 3a. The light reflectance refers to a regular reflectance. Accordingly, by detecting a light reflectance on the back surface of the n-type monocrystalline silicon substrate 1, and detecting the region with a different light reflectance, the position of the high-concentration boron-doped layer 3a within the back surface of the n-type monocrystalline silicon substrate 1 can be detected accurately. That is, by detecting a lower light-reflectance region within the back surface of the n-type monocrystalline silicon substrate 1, the position of the high-concentration boron-doped layer 3a within the back surface of the n-type monocrystalline silicon substrate 1 can be detected accurately. Due to this detection, at the time of printing a conductive paste for forming the back surface electrode 9, the high-concentration boron-doped layer 3a itself can be used as a patterned visible mark for the back-surface electrode 9. Therefore, in printing a conductive paste for forming the back-surface electrode 9, it is possible to align the printing position of the conductive paste with the high-concentration boron-doped layer 3a with a high degree of accuracy.

At the time of screen printing of a conductive paste for forming the back-surface electrode 9, the pattern position of the high-concentration boron-doped layer 3a is detected by detecting the amount of electromagnetic irradiation on the back surface of the n-type monocrystalline silicon substrate 1, and then detecting the light reflectance on the back surface of the n-type monocrystalline silicon substrate 1. In this case, for example, a plurality of sensors or cameras are provided within the region that corresponds to the outer shape of the n-type monocrystalline silicon substrate 1, and below these sensors or cameras, the n-type monocrystalline silicon substrate 1 is positioned with its back surface being directed upward. The amount of electromagnetic irradiation on the back surface of the n-type monocrystalline silicon substrate 1 is detected by the sensors or cameras. By using the detected data, that is, the data of light reflectance, the orientation and position of the screen-printing mask, formed with a desired screen-printing pattern, is aligned with the high-concentration boron-doped layer 3a formed on the back surface of the n-type monocrystalline silicon substrate 1. After the alignment of the screen-printing mask, a conductive paste is printed through an opening formed in the screen-printing mask, so as to position the back surface electrode 9 on the high-concentration boron-doped layer 3a. In order to recognize the image of a high-concentration doped region, which is difficult to optically recognize by image processing in the conventional manner, a highly functional image recognition system is required.

That is, the high-concentration boron-doped layer 3a, and the second low-concentration boron-doped layer 3c are formed, each of which has a different light reflectance attributable to the presence or absence of the minute irregularities 2. Therefore, the position of the high-concentration boron-doped layer 3a, on which a conductive paste for forming the back-surface electrode 9 needs to be printed, can be detected accurately. Accordingly, the alignment with a high degree of accuracy is possible in printing of a conductive paste for forming the back-surface electrode 9. This can prevent a decrease in the fill factor due to the increase in electrical resistance in the contact portion between the back-surface electrode 9 and the high-concentration boron-doped layer 3a, that is, the increase in contact resistance, which is caused when the back-surface electrode 9 is misaligned with the high-concentration boron-doped layer 3a. Therefore, a decrease in power generation efficiency can be prevented. Further, degradation of the photoelectric conversion properties, which is caused by recombination of the carriers in the high-concentration boron-doped layer 3a when it is not covered with the back-surface electrode 9, can be prevented. Therefore, a decrease in power generation efficiency can be prevented.

Furthermore, an increase in contact resistance between the back-surface electrode 9 and the high-concentration boron-doped layer 3a, which is caused by a misalignment of the back-surface electrode 9 with the high-concentration boron-doped layer 3a, is prevented so that an ohmic contact between the back-surface electrode 9 and the high-concentration boron-doped layer 3a can be achieved.

Any device that is capable of detecting the light reflectance on the back surface of the n-type monocrystalline silicon substrate 1 can be used for detecting the light reflectance on the surface of the high-concentration boron-doped layer 3a, and on the surface of the second low-concentration boron-doped layer 3c. As an example, the device detects a reflectance of the light with a wavelength of 700 nm.

On the surface of the first low-concentration boron-doped layer 3b, the minute irregularities 2 of the textured structure are partially processed and cut by etching. Therefore, the surface of the first low-concentration boron-doped layer 3b is made smaller than initially formed, and is in a state in which the silicon (100) plane, (111) plane, (110) plane, and (311) plane are present. On the surface of the first low-concentration boron-doped layer 3b, the amount of regular reflection, and thus the regular reflectance, are greater than the surface of the high-concentration boron-doped layer 3a, while being smaller than the surface of the second low-concentration boron-doped layer 3c. Accordingly, the position of the first low-concentration boron-doped layer 3b is detected by detecting the light reflectance, and this makes it possible to detect the position of the high-concentration boron-doped layer 3a within the back surface of the n-type monocrystalline silicon substrate 1 more accurately.

In the case where the width of a selective emitter region is reduced, a misalignment between the selective emitter region and a metal electrode may occur. When the metal electrode is formed out of alignment with a high-concentration selective emitter region, the electrical resistance in the contact portion between the metal electrode and the silicon substrate, that is, the contact resistance is increased. This leads to a reduction in the fill factor. In the high-concentration selective emitter region that is not covered with the metal electrode, degradation of the photoelectric conversion properties occurs due to recombination of the carriers generated by solar light within an impurity diffusion region. That is, a decrease in power generation efficiency is caused due to a misalignment between the high-concentration impurity diffusion region and the metal electrode. Therefore, in order to suppress a decrease in power generation efficiency caused by a misalignment between the metal electrode and the high-concentration impurity diffusion region that becomes a selective emitter region, it is necessary to increase the surface area of the high-concentration impurity diffusion region.

However, in the first embodiment, because of the differences in light reflectance on the back surface of the n-type monocrystalline silicon substrate 1, the position of the high-concentration boron-doped layer 3a within the back surface of the n-type monocrystalline silicon substrate 1 can be detected accurately. Therefore, in the first embodiment, the back-surface electrode 9 can be accurately aligned with the high-concentration boron-doped layer 3a. This can suppress a decrease in power generation efficiency caused by a misalignment between the metal electrode and the high-concentration impurity diffusion region that becomes a selective emitter region without the need for increasing the surface area of the high-concentration impurity diffusion region.

In the first embodiment, at the time of printing the back-surface electrode 9, it is unnecessary to perform alignment of a conductive paste using complicated image processing or a complicated detection system. Further, it is sufficient that a conductive paste is directly aligned with the high-concentration boron-doped layer 3a without using an alignment marker. At the time of, or prior to, forming a selective emitter region, it is unnecessary to separately form two or more conductive-paste alignment markers on the n-type monocrystalline silicon substrate 1 by laser or other methods. When the alignment markers are formed on the n-type monocrystalline silicon substrate 1 by laser or other methods, this results in damage to the n-type monocrystalline silicon substrate 1, and results in a reduction in the photoelectric conversion efficiency, manufacturing yield, and reliability.

The crystalline silicon solar cell according to the first embodiment illustrated in FIGS. 1 to 3 is obtained by performing the steps as described above.

In the above descriptions, the metal-electrode forming method using a fire-through process has been explained. However, the metal-electrode forming method is not limited thereto. It is also possible that etching paste, laser, or photolithography is used to form an opening in the back-surface silicon nitride film 8, and the back-surface silicon oxide film 7 on the high-concentration boron-doped layer 3a. Thereafter, a conductive paste is applied onto the high-concentration boron-doped layer 3a through the opening by screen printing, and is then fired at a high temperature of approximately 600° C. or higher. It is also possible that etching paste, laser, or photolithography is used to form an opening in the light-receiving-surface silicon nitride film 6, and the light-receiving-surface silicon oxide film 5 on the high-concentration phosphorus-doped layer 4a. Thereafter, a conductive paste is applied onto the high-concentration phosphorus-doped layer 4a through the opening by screen printing, and is then fired at a high temperature of approximately 600° C. or higher.

As an alternative method for forming a metal electrode, it is also possible that a layer of metal such as silver (Ag), copper (Cu), nickel (Ni), or titanium (Ti) is formed by means of plating.

In the above descriptions, the case has been explained in which the back-surface finger electrode 9a, and the back-surface bus electrode 9b are both formed on the high-concentration boron-doped layer 3a. However, the effects described above are also obtained when either the back-surface finger electrode 9a or the back-surface bus electrode 9b is only formed on the high-concentration boron-doped layer 3a. In this case, because the back-surface finger electrode 9a is thinner than the back-surface bus electrode 9b, and therefore more difficult to align, the improvement in alignment accuracy described above is more effective in forming only the back-surface finger electrode 9a.

Further, in the above descriptions, a textured structure is used, which is formed on the back surface simultaneously with forming a textured structure on the light receiving surface, which is designed to obtain the light trapping effect. Therefore, a one-time texture forming step contributes to both the light trapping effect and the alignment of the back-surface electrode 9.

As described above, in the first embodiment, a difference in light reflectance between the high-concentration boron-doped layer 3a, and the second low-concentration boron-doped layer 3c, attributable to the minute irregularities 2 is used. Therefore, the position of the high-concentration boron-doped layer 3a, on which a conductive paste for forming the back-surface electrode 9 is printed, can be detected accurately. The alignment with a high degree of accuracy is possible in printing of a conductive paste for forming the back-surface electrode 9. Consequently, according to the first embodiment, a solar cell with improved photoelectric conversion efficiency is obtained, in which a decrease in power generation efficiency, caused by a misalignment of the formation position of the back-surface electrode 9 relative to the high-concentration boron-doped layer 3a, is prevented.

### Second Embodiment

In a second embodiment of the present invention, a case is described in which a dopant paste is used as a method for forming a high-concentration boron-doped layer that becomes a selective emitter region. First, Step S10 described in the first embodiment is performed, and the surface of the n-type monocrystalline silicon substrate 1 is cleaned.

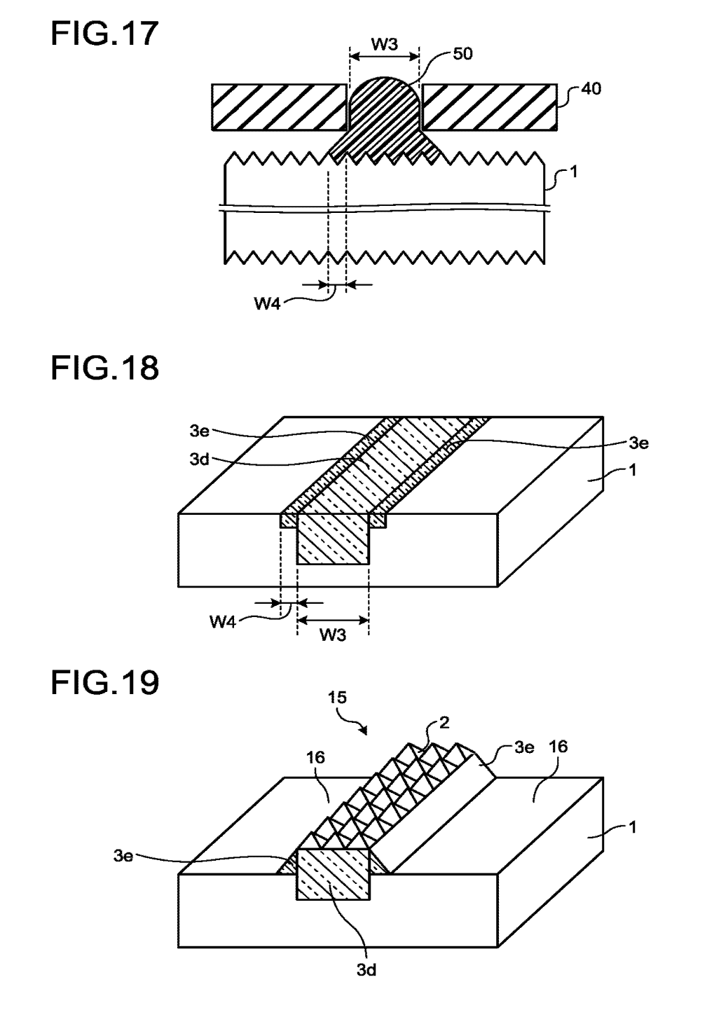

Next, a dopant paste is used to form a selective emitter region. When a dopant paste is used to form a selective emitter region, a dopant paste 50 that includes p-type impurities such as boron, and ingredients such as water, an organic solvent, and a thickening agent, is vertically printed and applied onto the back surface of the n-type monocrystalline silicon substrate 1 by using a mask by means of screen printing, as illustrated in FIG. 17. The mask 40, when it is aligned on the back surface of the n-type monocrystalline silicon substrate 1, is provided with an opening at the position corresponding to the region, where a selective emitter region is formed, on the back surface of the n-type monocrystalline silicon substrate 1. FIG. 17 is a schematic cross-sectional view illustrating a dopant-paste printing method in the second embodiment of the present invention.

After the dopant paste 50 is applied, the n-type monocrystalline silicon substrate 1 is heated at a high temperature of approximately 800° C. or higher to diffuse the boron included in the dopant paste 50 over the surface layer of the n-type monocrystalline silicon substrate 1 to form a high-concentration boron-doped layer 3d.

The dopant paste 50, having been applied in the manner as described above, spreads and extends in the planar direction of the n-type monocrystalline silicon substrate 1, and becomes thinner at the outer edge. The concentration of the boron, supplied and diffused over the surface layer of the n-type monocrystalline silicon substrate 1, varies due to the differences in thickness of the applied dopant paste 50. As illustrated in FIG. 18, the high-concentration boron-doped layer 3d, and a first low-concentration boron-doped layer 3e are formed on the n-type monocrystalline silicon substrate 1 in the same manner as in the first embodiment. In the high-concentration boron-doped layer 3d, boron having a mass number of 10, and boron having a mass number of 11 are diffused in a relatively higher concentration. In the first low-concentration boron-doped layer 3e, boron having a mass number of 10, and boron having a mass number of 11 are diffused in a relatively lower concentration from the dopant paste 50 that has spread, extended, and therefore been thinly applied. The high-concentration boron-doped layer 3d corresponds to the high-concentration boron-doped layer 3a, while the first low-concentration boron-doped layer 3e corresponds to the first low-concentration boron-doped layer 3b. FIG. 18 is a diagram illustrating an example of the shape of a selective emitter region formed by the dopant-paste printing method in the second embodiment of the present invention. FIG. 18 is a partially-cutaway perspective view on the back surface side of the n-type monocrystalline silicon substrate 1.

It is preferable that the high-concentration boron-doped layer 3d has a width W3 that ranges from 50 μm to 500 μm. A width W4 of the first low-concentration boron-doped layer 3e is approximately one-tenth of the width W3 of the high-concentration boron-doped layer 3d, although it depends on the conditions of the dopant paste 50, or the conditions such as a distance relation between the locations of the n-type monocrystalline silicon substrate 1 and the mask 40.

Next, high-temperature annealing treatment is performed at a temperature of approximately 900° C. or higher in order to electrically activate the boron implanted onto the n-type monocrystalline silicon substrate 1. In the annealing treatment conditions, the maximum temperature, the treatment time, and the atmosphere are changed to adjust the concentration of boron, mainly having a mass number of 11, in the high-concentration boron-doped layer 3d formed on the back surface of the n-type monocrystalline silicon substrate 1, such that the concentration becomes 1.0×10²⁰/cm³ or greater, and 1.0×10²¹/cm³ or less.

Next, in the same manner as Step S30 in the first embodiment, the back surface of the n-type monocrystalline silicon substrate 1 is etched to form the groove-opening portion 16. That is, selective etching is performed on the back surface of the n-type monocrystalline silicon substrate 1 by using the high-concentration boron-doped layer 3d as a mask, and using an alkaline solution as an etching solution. The etching amount depends on the boron surface-impurity concentration on the back surface of the n-type monocrystalline silicon substrate 1. The etching rate sharply decreases as the concentration becomes 1.0×10²⁰/cm³ or greater. Therefore, the etching rate is fastest on the n-type monocrystalline silicon substrate 1, followed by the first low-concentration boron-doped layer 3e, and slowest on the high-concentration boron-doped layer 3d. Therefore, the high-concentration boron-doped layer 3d can be used as an etching mask.

After the back surface of the n-type monocrystalline silicon substrate 1 is etched, the region of the high-concentration boron-doped layer 3d becomes the protruding portion 15 that protrudes from the other region on the etched back surface of the n-type monocrystalline silicon substrate 1 as illustrated in FIG. 19, similarly to the first embodiment. On the etched back surface of the n-type monocrystalline silicon substrate 1, the first low-concentration boron-doped layer 3e has a height that decreases as it is more distanced from the region of the high-concentration boron-doped layer 3d. The region, where the high-concentration boron-doped layer 3d is not formed, becomes the groove-opening portion 16. The depth of the groove-opening portion 16, which is a difference in height between the top surface of the high-concentration boron-doped layer 3d, and the etched back surface of the n-type monocrystalline silicon substrate 1, that is, the bottom surface of the groove-opening portion 16, is adjusted so as to become approximately 1 μm to 10 μm. FIG. 19 is a diagram illustrating an example of the shape of a selective emitter region in the second embodiment of the present invention. FIG. 19 is a partially-cutaway perspective view on the back surface side of the n-type monocrystalline silicon substrate 1.

When the boron surface-impurity concentration in the high-concentration boron-doped layer 3d is equal to or greater than 1.0×10²⁰/cm³, the etching rate decreases so sharply that the high-concentration boron-doped layer 3d is hardly etched. Therefore, as illustrated in FIG. 19, even after the etching, the minute irregularities 2 of the textured structure still remain on the surface of the high-concentration boron-doped layer 3d, similarly to the high-concentration boron-doped layer 3a.

Meanwhile, in the first low-concentration boron-doped layer 3e, the minute irregularities 2 of the textured structure are partially etched similarly to the first low-concentration boron-doped layer 3b. Therefore, the first low-concentration boron-doped layer 3e is in a state in which the silicon (100) plane, (111) plane, (110) plane, and (311) plane are present. A region, onto which boron is not implanted, on the back surface of the n-type monocrystalline silicon substrate 1 prior to the etching, that is, the bottom surface of the groove-opening portion 16 is removed more by etching at the fastest etching rate, resulting in a surface on which the minute irregularities 2 are more significantly processed.

In order to remove residues of the dopant-paste components on the surface of the n-type monocrystalline silicon substrate 1 prior to the etching, it is preferable to clean the surface of the substrate 1 with a cleaning solution that includes concentrated sulfuric acid and a hydrogen peroxide solution, a hydrofluoric acid solution, ozone water, or other types of solutions.

In the second embodiment, the groove-opening portion 16 is formed by isotropic etching using an alkaline solution as an etching solution. It is also possible that an acidic mixed solution that combines hydrofluoric acid, nitric acid, acetic acid, and hydrogen peroxide, is used as an etching solution for the isotropic etching. In this case, for example, the high-concentration boron-doped layer 3d, and the first low-concentration boron-doped layer 3e are formed by applying and heating the dopant paste 50, and thereafter the n-type monocrystalline silicon substrate 1 is etched by using the dopant paste 50 as a mask material, without removing it. The groove-opening portion 16 can thereby be formed. It is also possible that after the high-concentration boron-doped layer 3d is formed, an alkaline solution is further used to control the amount of etching to the groove-opening portion 16.

Thereafter, by performing Step S40 and the subsequent steps in the first embodiment, a crystalline silicon solar cell of the identical configuration to the crystalline silicon solar cell in the first embodiment illustrated in FIGS. 1 to 3 is obtained. The crystalline silicon solar cell according to the second embodiment, which is formed in the manner as described above, has a configuration identical to the crystalline silicon solar cell according to the first embodiment, except that the p-type impurity-doped layer 3 includes the high-concentration boron-doped layer 3d instead of the high-concentration boron-doped layer 3a, and also includes the first low-concentration boron-doped layer 3e instead of the first low-concentration boron-doped layer 3b.

As described above, in the second embodiment, the high-concentration boron-doped layer 3d that becomes a selective emitter region can be formed using the dopant paste 50. In the second embodiment, similarly to the first embodiment, a solar cell with improved photoelectric conversion efficiency is obtained, in which a decrease in power generation efficiency, caused by a misalignment of the formation position of the back surface electrode 9 relative to the high-concentration boron-doped layer 3d, is prevented.

### Third Embodiment

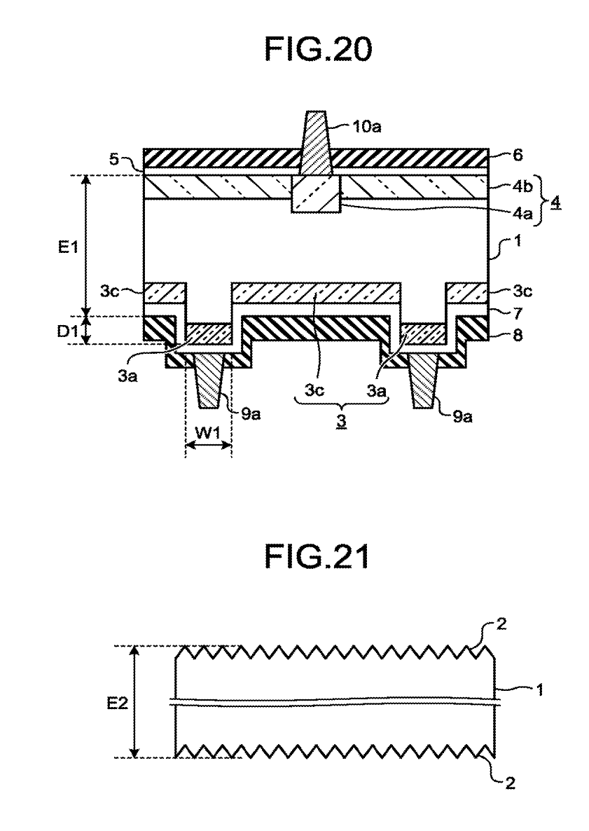

FIG. 20 is a schematic cross-sectional view of a crystalline silicon solar cell according to a third embodiment of the present invention. In the third embodiment, a case is described in which the n-type monocrystalline silicon substrate 1 in the crystalline silicon solar cell has a substrate thickness E1 of approximately 100 μm to 150 μm. The substrate thickness E1 of the n-type monocrystalline silicon substrate 1 is defined as a thickness from the bottom surface of the groove-opening portion 16 on the back surface of the n-type monocrystalline silicon substrate 1 to the top surface of the light receiving surface of the n-type monocrystalline silicon substrate 1. The heights of the upper points of the minute irregularities 2 are evened out.

The crystalline silicon solar cell according to the third embodiment basically has a configuration identical to the crystalline silicon solar cell according to the first embodiment, except for the configuration of the p-type impurity-doped layer 3. The crystalline silicon solar cell according to the third embodiment is different from the crystalline silicon solar cell according to the first embodiment in that the first low-concentration boron-doped layer 3b is not formed, and the p-type impurity-doped layer 3 is formed of the high-concentration boron-doped layer 3a and the second low-concentration boron-doped layer 3c, and in that the depth D1 of the groove-opening portion 16 is greater than that in the crystalline silicon solar cell according to the first embodiment. In FIG. 20, identical members as those in the first embodiment are denoted by like reference signs.

Conversion efficiency in a crystalline silicon solar cell is derived from “current×voltage×fill factor”. In order that a thinner silicon substrate obtains high photoelectric conversion efficiency, from the viewpoint of the balance between an increase in voltage and a decrease in current, there is an appropriate thickness for the silicon substrate. In the crystalline silicon solar cell according to the first embodiment, an appropriate value of the depth D1 of the groove-opening portion 16 differs depending on the thickness of a silicon substrate to be used.

The substrate thickness E1 is adjusted to become approximately 100 μm to 150 μm. Therefore, whilst solving the problems that the n-type monocrystalline silicon substrate 1 tends to be warped, or tends to be cracked, a high-voltage solar cell with high photoelectric conversion efficiency can be formed, while maintaining the mechanical strength of the n-type monocrystalline silicon substrate 1. When the substrate thickness E1 is less than 100 μm, the n-type monocrystalline silicon substrate 1 has a lower mechanical strength, and is more likely to be warped and cracked. When the substrate thickness E1 is greater than 150 μm, this leads to an imbalance between an increase in voltage and a decrease in current, and therefore reduces the photoelectric conversion efficiency. Accordingly, it is preferable that the substrate thickness E1 is approximately 100 μm to 150 μm. A case is described below, in which the substrate thickness E1 of the n-type monocrystalline silicon substrate 1 is approximately 100 μm to 150 μm.

FIGS. 21 to 24 are cross-sectional views of the relevant parts of the crystalline silicon solar cell according to the third embodiment of the present invention, which schematically illustrate an example of the steps of manufacturing this solar cell. First, as illustrated in FIG. 21, Step S10 is performed, which is a step of forming a textured structure made of the minute irregularities 2 described in the first embodiment. Thereafter, the surface of the n-type monocrystalline silicon substrate 1 is cleaned. FIG. 21 illustrates the n-type monocrystalline silicon substrate 1 in a state in which the textured structure made of the minute irregularities 2 is formed on both surfaces. In the present embodiment, a case is described in which a silicon substrate that has been sliced from a silicon ingot, and has a thickness of 200 μm, is used to form the n-type monocrystalline silicon substrate 1.

In the case where a silicon substrate that has been sliced from a silicon ingot, and has a thickness of 200 μm, is used, the surface of the silicon substrate is removed by approximately 10 μm on each surface in order to eliminate slicing damage. Due to this removal, the thickness of the silicon substrate results in approximately 180 μm. At the time of forming the textured structure, that is, at the time of forming the minute irregularities 2, when the thickness of the silicon substrate is decreased on each surface by approximately 10 μm, then the thickness of the silicon substrate after the formation of the minute irregularities 2 becomes approximately 160 μm. That is, after the formation of the textured structure, the n-type monocrystalline silicon substrate 1 has a substrate thickness E2 of approximately 160 μm.

The substrate thickness E2 is defined as a thickness from the upper point of the minute irregularities 2 formed on the back surface of the n-type monocrystalline silicon substrate 1, which becomes the back surface of the crystalline silicon solar cell, to the upper point of the minute irregularities 2 formed on the surface of the n-type monocrystalline silicon substrate 1, which becomes the light receiving surface of the crystalline silicon solar cell. This state shows that the n-type monocrystalline silicon substrate 1 has just undergone Step S10 described in the first embodiment with reference to FIG. 5. This state corresponds to the state in which the n-type monocrystalline silicon substrate 1 has a thickness of 160 μm, and has the textured structure on the substrate surface.

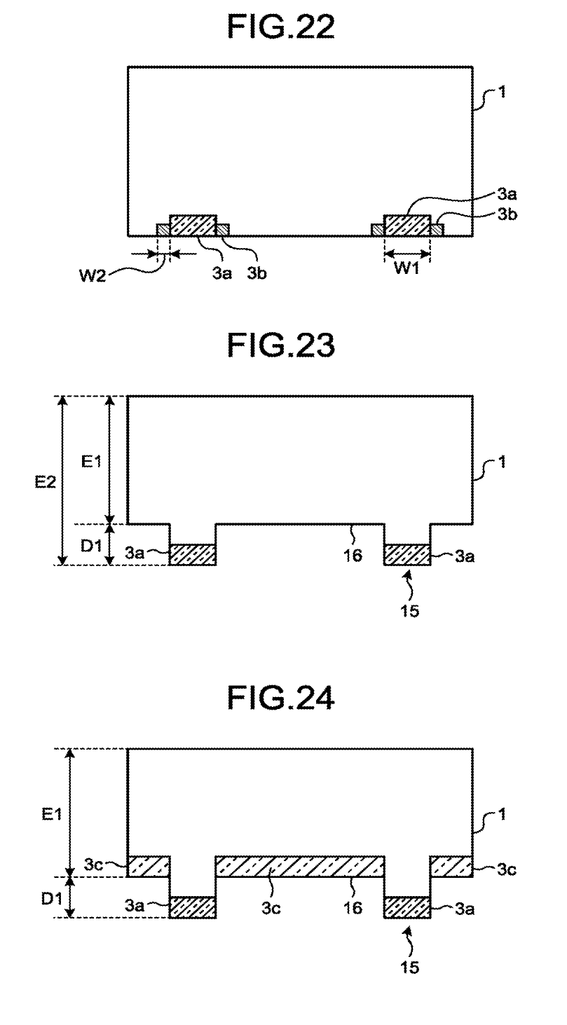

Next, Step S20 is performed in the same manner as in the first embodiment. The ion implantation method is used to form the high-concentration boron-doped layer 3a and the first low-concentration boron-doped layer 3b over the surface layer on the back surface of the n-type monocrystalline silicon substrate 1. It is also possible that the high-concentration boron-doped layer 3a is formed by the method illustrated in the second embodiment. In FIGS. 22 to 24, illustrations of the minute irregularities 2 are omitted.

Next, in the same manner as in the first embodiment, high-temperature annealing treatment is performed at a temperature of approximately 900° C. or higher in order to electrically activate the boron implanted onto the n-type monocrystalline silicon substrate 1.

Next, at Step S30, in the same manner as in the first embodiment, the back-surface of the n-type monocrystalline silicon substrate 1 is etched to form the protruding portion 15 and the groove-opening portion 16 as illustrated in FIG. 23. In the third embodiment, the etching depth for the back surface of the n-type monocrystalline silicon substrate 1 ranges from 10 μm to 60 μm. That is, in the third embodiment, the depth D1 of the groove-opening portion 16, which is a difference in height between the surface of the high-concentration boron-doped layer 3a, and the etched back surface of the n-type monocrystalline silicon substrate 1, is adjusted so as to become approximately 10 μm to 60 μm.

The minute irregularities 2 are formed and sized to have an average height of 1 μm to 10 μm. Therefore, the minute irregularities 2 are etched in the region other than the high-concentration boron-doped layer 3a by adjusting the depth D1 of the groove-opening portion 16 so as to become approximately 10 μm to 60 μm, while being greater than the height of the formed minute irregularities 2. The depth D1 of the groove-opening portion 16 is set equal to or greater than 10 μm, so that the minute irregularities 2 in the region, other than the high-concentration boron-doped layer 3a, are significantly processed. This can provide a significant difference in light reflectance between the high-concentration boron-doped layer 3a, and the region other than the high-concentration boron-doped layer 3a. When the depth D1 of the groove-opening portion 16 is set greater than 60 μm, the protruding portion 15 has a lower mechanical strength, and is more likely to break off. The depth D1 of the groove-opening portion 16, which is a difference in height between the surface of the high-concentration boron-doped layer 3a, and the back surface of the n-type monocrystalline silicon substrate 1, is set to approximately 10 μm to 60 μm. Therefore, the substrate thickness E1 of the n-type monocrystalline silicon substrate 1 can be set to approximately 100 μm to 150 μm.

At Step S30, the first low-concentration boron-doped layer 3b is removed as illustrated in FIG. 23. There will be no problem if the first low-concentration boron-doped layer 3b remains.

Next, at Step S40, boron ions are implanted onto the entire surface on the back surface side of the n-type monocrystalline silicon substrate 1, so as to form the second low-concentration boron-doped layer 3c over the surface layer of the bottom surface of the groove-opening portion 16 on which the high-concentration boron-doped layer 3a is not formed. At this time, the conditions of ion implantation are adjusted in such a manner as not to form the second low-concentration boron-doped layer 3c in the corresponding region below the high-concentration boron-doped layer 3a in the planar direction of the n-type monocrystalline silicon substrate 1, as illustrated in FIG. 24.

In this case, the high-concentration boron-doped layer 3a, and the second low-concentration boron-doped layer 3c are not electrically connected to each other directly. However, this does not significantly affect the carrier transfer because the distance between the high-concentration boron-doped layer 3a and the second low-concentration boron-doped layer 3c is short. There will be no problem if the second low-concentration boron-doped layer 3c is formed in the corresponding region below the high-concentration boron-doped layer 3a in the planar direction of the n-type monocrystalline silicon substrate 1.

Thereafter, Step S50 and the subsequent steps in the first embodiment are performed. The crystalline silicon solar cell according to the third embodiment illustrated in FIG. 20 is thereby obtained.

As described above, in the third embodiment, similarly to the first embodiment, a solar cell with improved photoelectric conversion efficiency is obtained, in which a decrease in power generation efficiency, caused by a misalignment of the formation position of the back surface electrode 9 relative to the high-concentration boron-doped layer 3a, is prevented.

In the third embodiment, the substrate thickness E1 is adjusted to become approximately 100 μm to 150 μm, and therefore a high-voltage solar cell with high photoelectric conversion efficiency can be formed, while maintaining the mechanical strength of the n-type monocrystalline silicon substrate 1. The depth D1 of the groove-opening portion 16 is set to approximately 10 μm to 60 μm. Therefore, while ensuring the mechanical strength of the solar cell, a significant difference in light reflectance can be provided between the high-concentration boron-doped layer 3a, and the region other than the high-concentration boron-doped layer 3a. Due to this configuration, in printing a conductive paste for forming the back-surface electrode 9, alignment of the printing position of the conductive paste with the high-concentration boron-doped layer 3a can be achieved with a high degree of accuracy.

### Fourth Embodiment

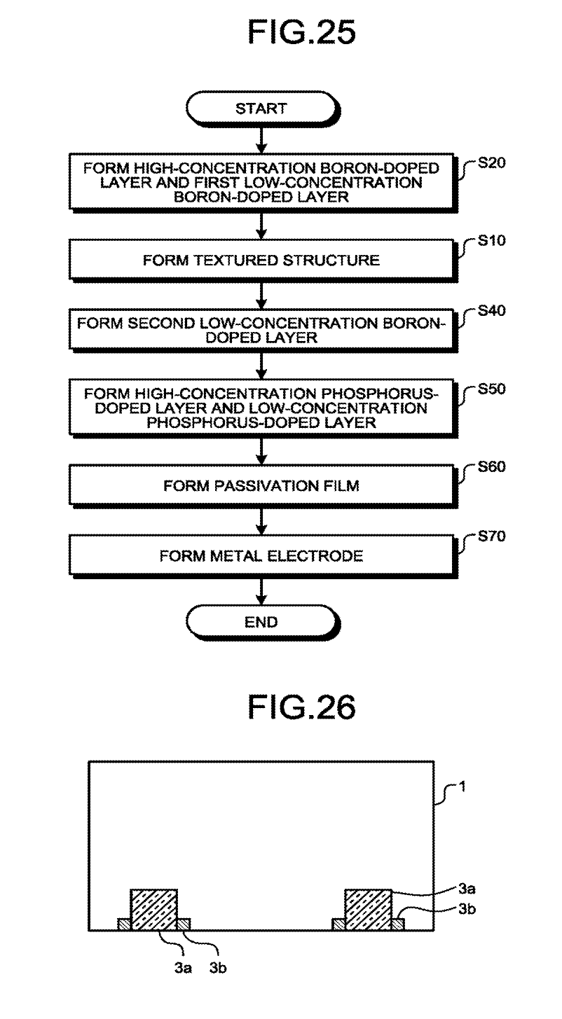

In the first to third embodiments described above, the case has been described, in which a crystalline silicon solar cell is formed by removing slicing damage from a silicon substrate that has been sliced from a silicon ingot, by forming a textured structure made of the minute irregularities 2 on both sides of the n-type monocrystalline silicon substrate 1, and by forming the high-concentration boron-doped layer 3a that becomes a selective emitter region, and the first low-concentration boron-doped layer 3b on the back surface side of the n-type monocrystalline silicon substrate 1, in the described order. In a fourth embodiment of the present invention, a case is described, in which a crystalline silicon solar cell is formed by removing slicing damage from a silicon substrate that has been sliced from a silicon ingot, and subsequently, by forming the high-concentration boron-doped layer 3a that becomes a selective emitter region, and the first low-concentration boron-doped layer 3b on the back surface side of the n-type monocrystalline silicon substrate 1 at Step S20, and by forming a textured structure made of the minute irregularities 2 on both sides of the n-type monocrystalline silicon substrate 1 at Step S10, in the described order, as illustrated in FIG. 25. FIG. 25 is a flowchart illustrating the manufacturing method of the crystalline silicon solar cell according to the fourth embodiment of the present invention. FIGS. 26 to 28 are cross-sectional views of the relevant parts of the crystalline silicon solar cell according to the fourth embodiment of the present invention, which schematically illustrate an example of the steps of manufacturing this solar cell.

In the fourth embodiment, the order of executing Steps S10 and S20 in the flowchart illustrated in FIG. 12 is interchanged. That is, after slicing damage is removed from a silicon substrate that has been sliced from a silicon ingot, the high-concentration boron-doped layer 3a, and the first low-concentration boron-doped layer 3b are formed at Step S20, as illustrated in FIG. 26. The width W1 of the high-concentration boron-doped layer 3a, and the width W2 of the first low-concentration boron-doped layer 3b are respectively identical to those in the first embodiment. The high-concentration boron-doped layer 3a, and the first low-concentration boron-doped layer 3b can be formed by either method described in the first embodiment or the second embodiment.

In this case, at the point in time when Step S20 has just been executed, the textured structure made of the minute irregularities 2 is not formed on the surface of the high-concentration boron-doped layer 3a or the first low-concentration boron-doped layer 3b. Step S20 is executed in the same manner as in the first embodiment. Therefore, the boron surface-impurity concentration in the high-concentration boron-doped layer 3a is set equal to or greater than 1.0×10²⁰/cm³.

Next, the textured structure made of the minute irregularities 2 is formed on both surfaces of the n-type monocrystalline silicon substrate 1 at Step S10. In this case, after the high-concentration boron-doped layer 3a is formed with a boron surface-impurity concentration of 1.0×10²⁰/cm³ or greater, wet etching using an alkaline solution is performed to form the textured structure. Therefore, the high-concentration boron-doped layer 3a is hardly etched, and accordingly the textured structure made of the minute irregularities 2 is not formed on the surface of the high-concentration boron-doped layer 3a.

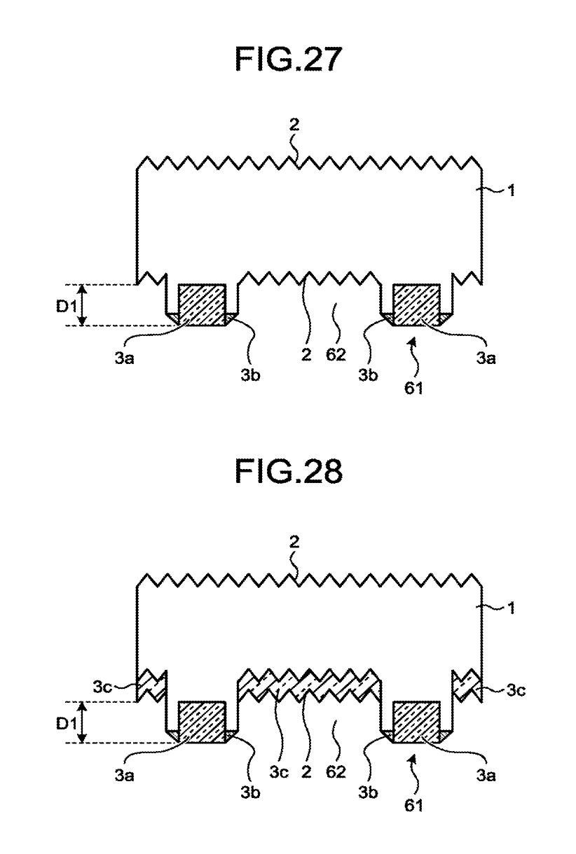

In the fourth embodiment, Step S10 also serves as Step S30 in the first embodiment, which is a step of forming the groove-opening portion 16 and the protruding portion 15. The high-concentration boron-doped layer 3a is hardly etched at the time of forming the textured structure. Therefore, the high-concentration boron-doped layer 3a functions as a mask in the wet etching for forming the textured structure. Accordingly, a region on the back surface of the n-type monocrystalline silicon substrate 1, other than the high-concentration boron-doped layer 3a, is etched to form a groove-opening portion 62 that is a second groove-opening portion. The textured structure made of the minute irregularities 2 is then formed on the bottom surface of the groove-opening portion 62. Further, after the back surface of the n-type monocrystalline silicon substrate 1 is etched, the region of the high-concentration boron-doped layer 3a becomes a protruding portion 61 that is a second protruding portion that protrudes from the other region on the etched back surface of the n-type monocrystalline silicon substrate 1 as illustrated in FIG. 27.

After the groove-opening portion 62, and the protruding portion 61 are formed at Step S30, the minute irregularities 2 are not formed on the surface of the high-concentration boron-doped layer 3a in the protruding portion 61. Therefore, the surface of the high-concentration boron-doped layer 3a, that is, the top surface of the protruding portion 61 is flat. That is, the surface of the high-concentration boron-doped layer 3a is constituted mainly by the silicon (111) plane. Meanwhile, the minute irregularities 2 of the textured structure are formed only on the bottom surface of the groove-opening portion 62. Therefore, the etched bottom surface of the groove-opening portion 62 includes the minute irregularities 2, and is accordingly constituted mainly by the silicon (111) plane. The minute irregularities 2 of the textured structure are formed on a part of the surface of the first low-concentration boron-doped layer 3b. Therefore, the surface of the first low-concentration boron-doped layer 3b is in a state in which the silicon (100) plane, (111) plane, (110) plane, and (311) plane are present.

Next, at Step S40, boron ions are implanted onto the entire surface on the back surface side of the n-type monocrystalline silicon substrate 1, so as to form the second low-concentration boron-doped layer 3c over the surface layer of the bottom surface of the groove-opening portion 62 on which the high-concentration boron-doped layer 3a is not formed. At this time, the conditions of ion implantation are adjusted in such a manner as not to form the second low-concentration boron-doped layer 3c in the corresponding region below the high-concentration boron-doped layer 3a in the planar direction of the n-type monocrystalline silicon substrate 1, as illustrated in FIG. 28.

In this case, the high-concentration boron-doped layer 3a, and the second low-concentration boron-doped layer 3c are not electrically connected to each other directly. However, this does not significantly affect the carrier transfer because the distance between the high-concentration boron-doped layer 3a and the second low-concentration boron-doped layer 3c is short. There will be no problem if the second low-concentration boron-doped layer 3c is formed in the corresponding region below the high-concentration boron-doped layer 3a, and below the first low-concentration boron-doped layer 3b in the planar direction of the n-type monocrystalline silicon substrate 1.

Thereafter, Step S50 and the subsequent steps in the first embodiment are performed. The crystalline silicon solar cell according to the fourth embodiment is thereby obtained.

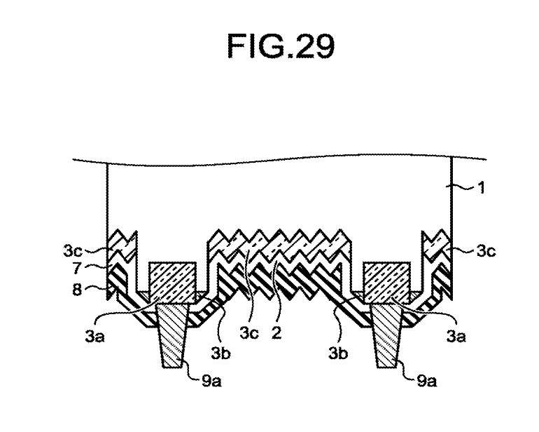

FIG. 29 is an enlarged schematic cross-sectional view illustrating the p-type impurity-doped layer 3 of the crystalline silicon solar cell according to the fourth embodiment of the present invention. The crystalline silicon solar cell according to the fourth embodiment, manufactured in the manner as described above, basically has a configuration identical to the crystalline silicon solar cell according to the first embodiment, except for the configuration of the p-type impurity-doped layer 3. The crystalline silicon solar cell according to the fourth embodiment is mainly different from the crystalline silicon solar cell according to the first embodiment in that the minute irregularities 2 of the textured structure are not formed on the surface of the high-concentration boron-doped layer 3a, while the minute irregularities 2 of the textured structure are formed on the bottom surface of the groove-opening portion 62, that is, on the surface of the second low-concentration boron-doped layer 3c. That is, in the crystalline silicon solar cell according to the fourth embodiment, the minute irregularities 2 of the textured structure are formed in a region other than the region where the minute irregularities 2 are formed in the crystalline silicon solar cell according to the first embodiment. In FIG. 29, identical members as those in the first embodiment are denoted by like reference signs.

As described above, in the crystalline silicon solar cell according to the fourth embodiment, on the surface of the high-concentration boron-doped layer 3a, the amount of regular reflection is greater, and therefore the regular reflectance is also greater, than the surface of the second low-concentration boron-doped layer 3c. Accordingly, by detecting a light reflectance on the back surface of the n-type monocrystalline silicon substrate 1, and detecting the region with a different light reflectance, the position of the high-concentration boron-doped layer 3a within the back surface of the n-type monocrystalline silicon substrate 1 can be detected accurately. That is, by detecting a higher light-reflectance region within the back surface of the n-type monocrystalline silicon substrate 1, the position of the high-concentration boron-doped layer 3a within the back surface of the n-type monocrystalline silicon substrate 1 can be detected accurately. Due to this detection, at the time of printing a conductive paste for forming the back-surface electrode 9, the high-concentration boron-doped layer 3a itself can be used as a patterned visible mark for the back-surface electrode 9. Therefore, in printing a conductive paste for forming the back-surface electrode 9, it is possible to align the printing position of the conductive paste with the high-concentration boron-doped layer 3a with a high degree of accuracy.

Consequently, according to the fourth embodiment, a solar cell with improved photoelectric conversion efficiency is obtained, in which a decrease in power generation efficiency, caused by a misalignment of the formation position of the back-surface electrode 9 relative to the high-concentration boron-doped layer 3a, is prevented.

In the fourth embodiment, in the same manner as in the first to third embodiments, a textured structure is formed on the back surface simultaneously with forming a textured structure on the light receiving surface, which is designed to obtain the light trapping effect, and this textured structure on the back surface is used for the alignment of the formation position of the back-surface electrode 9. Therefore, a one-time texture forming step contributes to both the light trapping effect and the alignment of the back-surface electrode 9.

Further, in the fourth embodiment, a selective emitter region is formed on the back surface of the n-type monocrystalline silicon substrate 1. Because the groove-opening portion 62 includes the minute irregularities 2 in which the light reflectance is sufficiently low, the groove-opening portion 62 can also be formed on the light receiving surface that becomes the surface of the solar cell, and be used in order to obtain the light trapping effect.

Next, the crystalline silicon solar cell according to the first to fourth embodiments is described based on the specific examples.

### First Example

A crystalline silicon solar cell was manufactured according to the manufacturing method described in the first embodiment, and was defined as a crystalline silicon solar cell of a first example. The boron concentration in the high-concentration boron-doped layer 3a was adjusted to become 1.0×10²⁰/cm³ or greater, and 1.0×10²¹/cm³ or less. The boron concentration in the first low-concentration boron-doped layer 3b was adjusted to become 5.0×10¹⁹/cm³ or greater, and less than 1.0×10²⁰/cm³. The boron concentration in the second low-concentration boron-doped layer 3c was adjusted to become 5.0×10¹⁸/cm³ or greater, and 5.0×10¹⁹/cm³ or less. The minute irregularities 2 were formed and sized to have an average interval of approximately 3 μm, and an average height of approximately 3 μm.

### Second Example

A crystalline silicon solar cell was manufactured according to the manufacturing method described in the second embodiment, and was defined as a crystalline silicon solar cell of a second example. The boron concentration in the high-concentration boron-doped layer 3d was adjusted to become 1.0×10²⁰/cm³ or greater, and 1.0×10²¹/cm³ or less. The boron concentration in the first low-concentration boron-doped layer 3e was adjusted to become 5.0×10¹⁹/cm³ or greater, and less than 1.0×10²⁰/cm³. The boron concentration in the second low-concentration boron-doped layer 3c was adjusted to become 5.0×10¹⁸/cm³ or greater, and 5.0×10¹⁹/cm³ or less. The minute irregularities 2 were formed and sized to have an average interval of approximately 3 μm, and an average height of approximately 3 μm.

### Third Example

A crystalline silicon solar cell was manufactured according to the manufacturing method described in the third embodiment, and was defined as a crystalline silicon solar cell of a third example. Each of the high-concentration boron-doped layer 3a, the first low-concentration boron-doped layer 3b, and the second low-concentration boron-doped layer 3c had a boron concentration identical to the first example. The depth D1 of the groove-opening portion was adjusted so as to set the substrate thickness E1 to approximately 120 μm.

### Fourth Example

A crystalline silicon solar cell was manufactured according to the manufacturing method described in the fourth embodiment, and was defined as a crystalline silicon solar cell of a fourth example. Each of the high-concentration boron-doped layer 3a, the first low-concentration boron-doped layer 3b, and the second low-concentration boron-doped layer 3c had a boron concentration identical to the first example. The top surface of the protruding portion 61 was flat. The minute irregularities 2, sized to have an average interval of approximately 3 μm, and an average height of approximately 3 μm, were formed on the surface of the groove-opening portion 62.

### First Comparative Example

A high-concentration boron-doped layer that is a selective emitter region was formed by the ion implantation method using a mask in the same manner as in the first example. The boron concentration in the high-concentration boron-doped layer was adjusted to become 1.0×10²⁰/cm³ or greater, and 1.0×10²¹/cm³ or less. A crystalline silicon solar cell was manufactured through the same steps as in the first example, except that a low-concentration boron-doped layer was formed by implanting boron ions onto the entire surface on the back surface side of the n-type monocrystalline silicon substrate, instead of performing etching on the back surface of the n-type monocrystalline silicon substrate by using the high-concentration boron-doped layer as a mask. This crystalline silicon solar cell was defined as a crystalline silicon solar cell of a first comparative example.

### Second Comparative Example

A high-concentration boron-doped layer that is a selective emitter region was formed by the dopant-paste printing method using a mask in the same manner as in the first example. The boron concentration in the high-concentration boron-doped layer was adjusted to become 1.0×10²⁰/cm³ or greater, and 1.0×10²¹/cm³ or less. A crystalline silicon solar cell was manufactured through the same steps as in the second example, except that a low-concentration boron-doped layer was formed by implanting boron ions onto the entire surface on the back surface side of the n-type monocrystalline silicon substrate, instead of performing etching on the back surface of the n-type monocrystalline silicon substrate by using the high-concentration boron-doped layer as a mask. This crystalline silicon solar cell was defined as a crystalline silicon solar cell of a second comparative example.

### Third Comparative Example

Prior to forming the high-concentration boron-doped layer that is a selective emitter region, two or more alignment markers were formed by laser on the back surface of the n-type monocrystalline silicon substrate. At the time of forming a selective emitter region by using a dopant paste, the position of the selective emitter region was adjusted so as to correspond with the alignment markers. The crystalline silicon solar cell was manufactured through the same steps as in the second comparative example, except that the image of the back surface of the n-type monocrystalline silicon substrate was captured by an image processing device, and the captured image was used to form and align the back-surface electrode 9 with the position of the selective emitter region. This crystalline silicon solar cell was defined as a crystalline silicon solar cell of a third comparative example.

In each crystalline silicon solar cell of the examples and comparative examples described above, a reflectance of the light with a wavelength of 700 nm was measured on the back surface prior to forming a back-surface electrode. The light reflectance was measured on the high-concentration boron-doped layer, and the low-concentration boron-doped layer. The low-concentration boron-doped layer is a region corresponding to the second low-concentration boron-doped layer 3c. The output of the photoelectric conversion efficiency of each crystalline silicon solar cell was measured by a solar simulator. The measurement results are illustrated in Table 1.

TABLE 1

| | Light reflectance (%) | | |
|---|---|---|---|
| | High- | Low- | Photoelectric |
| | concentration | concentration | conversion |
| | boron-doped | boron-doped | efficiency |
| | layer | layer | (Eff) (%) |
| First example | 10.2 | 25 | 20.1 |
| Second example | 10.1 | 24.5 | 20 |
| Third example | 10.3 | 25.5 | 20.2 |
| Fourth example | 35 | 10.1 | 20.5 |
| First | 10.2 | 10.3 | 19.1 |
| comparative | | | |
| example | | | |
| Second | 10.1 | 10.2 | 19.2 |
| comparative | | | |
| example | | | |
| Third | 10.3 | 10.2 | 19.2 |
| comparative | | | |
| example | | | |

As can be understood from Table 1, the output characteristics were improved in the first to fourth examples, as compared to the first to third comparative examples. This is considered as the effect of preventing a decrease in photoelectric conversion efficiency due to a misalignment of the formation position of the back-surface electrode 9, and due to damage to the n-type monocrystalline silicon substrate caused when the alignment markers are formed by laser, in the crystalline silicon solar cell having a selective emitter structure.

In the first to third examples, the light reflectance on the low-concentration boron-doped layer is significantly greater than the light reflectance on the high-concentration boron-doped layer. This is because etching is performed on the back surface of the n-type monocrystalline silicon substrate by using the high-concentration boron-doped layer as a mask. In the fourth example, the light reflectance on the high-concentration boron-doped layer is significantly greater than the light reflectance on the low-concentration boron-doped layer. This is because instead of forming the minute irregularities 2 of the textured structure on the surface of the high-concentration boron-doped layer 3a, the minute irregularities 2 of the textured structure are formed on the surface of the second low-concentration boron-doped layer 3c. In the first to fourth examples, the alignment of the back-surface electrode 9 is accurately performed by using the difference in light reflectance between the high-concentration boron-doped layer and the low-concentration boron-doped layer. This prevents a decrease in photoelectric conversion efficiency due to a misalignment of the formation position of the back-surface electrode 9.

On the other hand, in the first to third comparative examples, the value of the light reflectance on the high-concentration boron-doped layer is almost equal to that on the low-concentration boron-doped layer. This is because etching using the high-concentration boron-doped layer as a mask is not performed on the back surface of the n-type monocrystalline silicon substrate. Therefore, the alignment of the back-surface electrode is performed by using a slight difference in light reflectance between the high-concentration boron-doped layer and the low-concentration boron-doped layer. However, the alignment accuracy for the back-surface electrode is relatively lower, and accordingly the photoelectric conversion efficiency is lower than the first to fourth examples.

In view of the facts described above, it is considered that a solar cell with improved photoelectric conversion efficiency, manufacturing yield, and reliability, can be obtained in the first to fourth examples.

The configurations described in the above embodiments are only examples of the contents of the present invention. The invention of the present application is not limited to the above embodiments, and these embodiments can be variously modified in their implementing stages without departing from the scope thereof. Furthermore, the above embodiments include inventions of various stages, and various inventions can be extracted by appropriate combinations of a plurality of constituent elements disclosed therein. For example, even when some of the constituent elements among all of the constituent elements described in the respective first to fourth embodiments described above are omitted, as long as the problems mentioned in the section of Technical Problem can be solved and the effects mentioned in the section of Effects of the Invention can be obtained, the configuration from which some of the constituent elements are omitted can be extracted as an invention. In addition, the constituent elements employed in the first to fourth embodiments described above can be combined as appropriate.

### REFERENCE SIGNS LIST

1 n-type monocrystalline silicon substrate
2 minute irregularities
3 p-type impurity-doped layer
3a high-concentration boron-doped layer
3b first low-concentration boron-doped layer
3c second low-concentration boron-doped layer
3d high-concentration boron-doped layer
3e first low-concentration boron-doped layer
4 n-type impurity-doped layer
4a high-concentration phosphorus-doped layer
4b low-concentration phosphorus-doped layer
9 back-surface electrode
9a back-surface finger electrode
9b back-surface bus electrode
10 light-receiving-surface electrode
10a light-receiving-surface finger electrode
10b light-receiving-surface bus electrode
15, 61 protruding portion
16, 62 groove-opening portion
20, 40 mask
30 boron ion beam
31 straight component
32 scattering component
50 dopant paste
W1 width of high-concentration boron-doped layer
W2 width of first low-concentration boron-doped layer
W3 width of high-concentration boron-doped layer
W4 width of first low-concentration boron-doped layer

1: A solar cell manufacturing method comprising:
a first step of forming, on one surface of a first conductivity-type semiconductor substrate, a first doped layer in which second conductivity-type impurities are diffused in a first concentration, and a second doped layer in which the second conductivity-type impurities are diffused in a second concentration lower than the first concentration, where the second doped layer has surface roughness different from the first doped layer; and
a second step of forming a metal electrode on the first doped layer to be electrically connected to the first doped layer, wherein
the first step includes
a third step of forming a first textured structure on one surface of the semiconductor substrate,
a fourth step of forming the first doped layer in a predetermined pattern over a surface layer on a surface layer of one surface of the semiconductor substrate on which the first textured structure has been formed,
a fifth step of etching a region on one surface of the semiconductor substrate, other than the first doped layer, to form a first groove-opening portion, and
a sixth step of forming the second doped layer at least over a surface layer of the first groove-opening portion,
at the second step, a position of the first doped layer is detected based on a difference in light reflectance between the first doped layer and the second doped layer, which results from a difference in surface roughness between the first doped layer and the second doped layer, and then the metal electrode is formed in alignment with a detected position of the first doped layer.

2. (canceled)

3: The solar cell manufacturing method according to claim 1, wherein at the fifth step, the first groove-opening portion is formed to have a bottom surface on which the first textured structure has been processed and partially removed by wet etching or etching using an etching paste.

4: The solar cell manufacturing method according to claim 1, wherein at the fourth step, a mask with an opening that corresponds to a shape of the first doped layer is used to implant the second conductivity-type impurities onto a surface layer on one surface of the semiconductor substrate through the opening by an ion implantation method, and thereafter heat treatment is performed on the semiconductor substrate.

5: The solar cell manufacturing method according to claim 1, wherein at the fourth step, a mask with an opening that corresponds to a shape of the first doped layer is used to apply a paste including the second conductivity-type impurities onto a surface layer on one surface of the semiconductor substrate through the opening, and thereafter heat treatment is performed on the semiconductor substrate.

6: The solar cell manufacturing method according to claim 1, wherein the semiconductor substrate is a monocrystalline silicon substrate, and the one surface is a (100) plane.

7: The solar cell manufacturing method according to claim 1, wherein a passivation film that covers the first groove-opening portion is formed.

8. (canceled)

9: A solar cell comprising:
a n-type semiconductor substrate that includes a doped layer, in which p-type impurity elements are diffused, over a surface layer on one surface of the semiconductor substrate, the one surface being a back surface opposed to a light receiving surface; and
a metal electrode that is formed on one surface of the semiconductor substrate, and that is electrically connected to the doped layer, wherein
the doped layer includes
a first doped layer in which p-type impurities are diffused in a first concentration over a surface layer of a protruding portion that is formed in a predetermined pattern on one surface of the semiconductor substrate and has a first textured structure on a top surface thereof, where the first doped layer is electrically and mechanically connected to the metal electrode, and
a second doped layer in which p-type impurities are diffused in a second concentration lower than the first concentration, in a region of a groove-opening portion, other than the first doped layer, on one surface of the semiconductor substrate, the second doped layer having a second textured structure on a top surface thereof, and
surface roughness on the top surface of the first doped layer is greater than that on the top surface of the second doped layer and regular reflectance on the too surface of the first doped layer is smaller than that on the too surface of the second doped layer.

10: The solar cell according to claim 9, wherein
a top surface of the first doped layer is mainly constituted by a (111) plane, and has surface roughness of 1 μm or greater, and less than 10 μm, and
a difference in height between a top surface of the first doped layer and a top surface of the second doped layer is greater than surface roughness of the first doped layer.

11. (canceled)

12: The solar cell according to claim 10, wherein
the first concentration is 1.0×10²⁰/cm³ or greater, and 1.0×10²¹/cm³ or less, and
the second concentration is 5.0×10¹⁸/cm³ or greater, and 5.0×10¹⁹/cm³ or less.

13: The solar cell according to claim 10, wherein a difference in height between a top surface of the first doped layer and a top surface of the second doped layer is 1 μm or greater, and 60 μm or less.
